(19) United States
(12) Patent Application Publication
(10) Pub. No.: US 2026/0100514 A1
(43) Pub. Date: Apr. 9, 2026

(54) ANTENNA MODULE IMPLEMENTED IN MULTI-LAYERED PACKAGE

(71) Applicant: LG ELECTRONICS INC., Seoul (KR)

(72) Inventors: Yusuhk SUH, Seoul (KR); Dongik LEE, Seoul (KR)

(73) Assignee: LG ELECTRONICS INC., Seoul (KR)

(21) Appl. No.: 19/347,431

(22) Filed: Oct. 1, 2025

(30) Foreign Application Priority Data
Oct. 4, 2024 (KR) 10-2024-0135038

(51) Int. Cl. H01Q 9/04; H01Q 3/36

(52) U.S. Cl. CPC H01Q 9/0478; H01Q 3/36; H01Q 9/0414

(57) ABSTRACT

Provided is an antenna module including a printed circuit board (PCB), and an array antenna portion arranged on a first outermost surface of the PCB, and including first and second array antennas arranged in a first region and a second region based on a first axial direction. The first array antenna may include first and second patch antennas which are stacked to overlap each other. The second array antenna may include third and fourth patch antennas which are stacked to overlap each other. The first and third patch antennas arranged on the first outermost surface may be arranged spaced apart at a first gap in a second axial direction. First and second groups of the fourth patch antennas arranged in third and fourth regions in the second axial direction may be arranged spaced apart at a second gap along the second axial direction.

### CROSS-REFERENCE TO RELATED APPLICATIONS

Pursuant to 35 U.S.C. § 119(a), this application claims the benefit of earlier filing date and right of priority to Korean Patent Application No. 10-2024-0135038, filed on Oct. 4, 2024, the contents of which are all hereby incorporated by reference herein in their entireties.

### BACKGROUND

### 1. Field

The disclosure relates to a multi-layered circuit type antenna package for millimeter wave band communication.

### 2. Description of the Related Art

A millimeter wave (mmWave) band communication method, which is being developed to transmit GBps-level high-speed, large-capacity AV data, can transmit large-capacity data several times faster than existing short/mid-range communication methods, such as WiFi, WLAN, WPAN, etc.

This millimeter wave band communication method, unlike the existing short/mid-range communication methods, is very difficult to be implemented in a manner of connecting an antenna and an RFIC, which are separately provided, with a cable. In the millimeter wave band, a signal attenuation phenomenon is dozens of times higher than those in existing commercial frequency bands. A signal cable dedicated to the millimeter wave band is a major obstacle to the commercialization of 60GHz communication modules, due to unit prices reaching up to tens of dollars. Therefore, in the millimeter wave band, a technology for designing antenna and package are required to dispose an antenna and an RFIC within the shortest distance, to suppress signal loss and attenuation.

As the related art technology for implementing a millimeter wave band antenna/package, a technology of embedding an antenna and a stripline or microstrip type signal transmission line in a multi-layer circuit and electrically connecting the same to an RFIC is widely used. This method implements a transverse electromagnetic (TEM) mode required for a wideband signal line, thereby widening a bandwidth required in the millimeter wave band.

The multi-layer circuit type using the stripline or microstrip is an ideal way for realizing antenna performance. However, in the case of a stripline, a signal line is arranged on a middle layer and ground layers are arranged above and below the signal line, so at least three layers are required. In the case of a microstrip, at least two layers are required, including a layer where a signal line is arranged and a ground layer arranged above or below the signal line. Therefore, when designing a multi-layered circuit by combination of antenna, RF interface, inner cavity, power line, etc., the number of layers stacked reaches approximately 7 to 10 layers. In the case of a low temperature co-fired ceramic (LTCC) process that implements this, it needs high production costs, which is an obstacle to the commercialization of the millimeter wave communication technology.

A multi-layered circuit type antenna module may be configured to include different array antennas oriented in different directions. In this regard, a beamforming signal formed by an array antenna oriented in a specific direction supports only a specific polarization. In an indoor environment where an antenna module is positioned, a radio environment also changes depending on surrounding influences. Accordingly, the polarization direction of the beamforming signal formed by the array antenna also changes. As the polarization direction changes due to changes in the radio environment, the quality of signals transmitted and received through the array antenna deteriorates.

### SUMMARY

An aspect of the disclosure is to suppress deterioration of quality of transmitted and received signals due to changes in polarization direction according to changes in radio environment.

Another aspect of the disclosure is to provide a structure with minimized stacked layers as a multi-layered circuit type antenna package for millimeter wave band communication.

Another aspect of the disclosure is to provide a structure that minimizes a signal phase difference for each patch in a patch array antenna structure for millimeter wave band communication.

According to one or more embodiments, an antenna module implemented as a multi-layered package includes a printed circuit board (PCB), and an array antenna portion arranged on a first outermost surface of the PCB, and including first and second array antennas arranged in a first region and a second region based on a first axial direction. The first array antenna may include first and second patch antennas which are stacked to overlap each other. The second array antenna may include third and fourth patch antennas which are stacked to overlap each other. The first and third patch antennas arranged on the first outermost surface may be arranged spaced apart at a first gap in a second axial direction. First and second groups of the fourth patch antennas arranged in third and fourth regions in the second axial direction may be arranged spaced apart at a second gap along the second axial direction.

An antenna module implemented as a multi-layered package according to an embodiment includes a printed circuit board (PCB) having a plurality of layers, a phased array antenna portion arranged on a first outermost surface of the PCB and including a plurality of antenna elements, wherein the phased array antenna portion has a first region and a second region based on a first axial direction, the phased array antenna portion has a third region and a fourth region based on a second axial direction, and the first axis and the second axis are orthogonal to each other, a radio frequency integrated circuit (RFIC) chip bonded to a second outermost surface of the PCB, and a plurality of signal connection lines configured to electrically connect the RFIC chip and the phased array antenna portion. The plurality of antenna elements may include a first array antenna and a second array antenna.

In an embodiment, the first array antenna arranged in the first region may include first patch antennas arranged on the first outermost surface of the PCB, the first patch antennas being arranged spaced apart at a first gap along the second axial direction, and second patch antennas arranged on one of the plurality of layers inside the PCB. Portions of the first patch antennas and portions of the second patch antennas may be stacked to overlap each other, and centers of the first patch antennas and centers of the second patch antenna may be aligned along a same axis.

The first array antenna arranged in the second region may include third patch antennas arranged on the first outermost surface of the PCB, the third patch antennas being arranged spaced apart at the first gap along the second axial direction, and fourth patch antennas arranged on one of the plurality of layers inside the PCB. portions of the third patch antennas and portions of the fourth patch antennas may be stacked to overlap each other. A first group of the fourth patch antennas may be arranged in the third region, and may be positioned at a second gap along the second axial direction. A second group of the fourth patch antennas may be arranged in the fourth region, and may be positioned at the second gap along the second axial direction.

The multi-layered circuit type antenna package described above provides a dual polarization antenna structure which can suppress quality of signals transmitted and received through array antennas from being deteriorated due to changes in polarization direction according to changes in radio environment.

The multi-layered circuit type antenna package presents a structure which can wirelessly transmit broadband signals by minimizing the number of stacked layers.

The multi-layered circuit type antenna package has low loss during signal transmission and is economical in process cost.

Further scope of applicability of the disclosure will become apparent from the following detailed description. It should be understood, however, that the detailed description and specific examples, such as the preferred embodiment of the present disclosure, are given by way of illustration only, since various modifications and alternations within the idea and similar scope of the disclosure will be apparent to those skilled in the art.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view of a structure in which an antenna module is coupled to a structure arranged in an electronic device according to an embodiment;

FIG. 2 is a front view of a substrate on which the antenna module is arranged;

FIG. 3 shows a cross-sectional view and a three-dimensional structure of a substrate on which the antenna module of FIG. 2 is arranged;

FIG. 4 shows front and cross-sectional views of a horizontal polarization antenna in a first region of the antenna module;

FIG. 5 shows front and cross-sectional views of a vertical polarization antenna in a second region of the antenna module;

FIG. 6A is a lateral view of a partial region of the antenna module with patch antennas having an overlap structure, shown in FIG. 5;

FIG. 6B is a view showing sizes and gaps of radiators arranged on different layers and gaps between the radiators and a ground wall in the lateral view of the antenna module of FIG. 6A;

FIG. 7 shows via wall formation structures according to various embodiments;

FIGS. 8A and 8B are front views of the antenna modules of FIGS. 4 and 5 shown for each layer;

FIG. 9A is a view of first and third layers of the antenna module of FIG. 8A;

FIG. 9B is a view of first and fifth layers of the antenna module of FIG. 8A;

FIG. 9C is a view of first and seventh layers of the antenna module of FIGS. 8A and 8B;

FIG. 10A is a view of tenth and twelfth layers on which patch antennas of the antenna module of FIG. 8B are stacked;

FIG. 10B is a view of an overlap arrangement structure of horizontal polarization antennas arranged in an array antenna arrangement region of the antenna module of FIG. 10A; and

FIG. 10C is a view of an overlap arrangement structure of vertical polarization antennas arranged in the array antenna arrangement region of the antenna module of FIG. 10A.

### DETAILED DESCRIPTION OF THE EMBODIMENTS

A description will now be given in detail of specific embodiments of the present disclosure, together with drawings.

Hereinafter, a description will be given in more detail of embodiments related to the disclosure, with reference to the accompanying drawings. In general, a suffix such as "module" and "unit" may be used to refer to elements or components. Use of such a suffix herein is merely intended to facilitate description of the specification, and the suffix itself is not intended to give any special meaning or function.

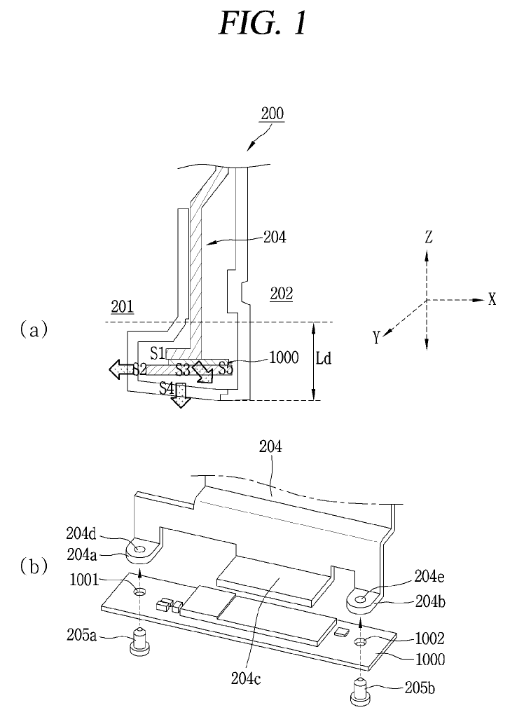

Meanwhile, the antenna module according to the disclosure may be arranged in a horizontal arrangement structure. In this regard, FIG. 1 is a view of a structure in which an antenna module is coupled to a structure arranged in an electronic device according to an embodiment. (a) of FIG. 1 shows a structure that an antenna module 1000 is arranged in a lower region of an electronic device 200. (b) of FIG. 1 shows a structure that the antenna module 1000 is coupled to a support structure, such as a heat sink 204.

Referring to (a) of FIG. 1, the antenna module 1000 may be coupled to an end portion of the heat sink 204 arranged in a space between a first cover 201 and a second cover 202. The antenna module 1000 may include a plurality of surfaces S1 to S6. A first surface S1 of the plurality of surfaces may face a downward direction of the electronic device 200, and a second surface S2 may face an upward direction of the electronic device 200. A third surface S3 of the plurality of surfaces may face a left direction of the electronic device 200, and a fourth surface S4 may face a right direction of the electronic device 200. A fifth surface S5 of the plurality of surfaces may face a front direction of the electronic device 200, and a sixth surface S6 may face a rear direction of the electronic device 200.

A length of a lower end portion of the first cover 201 to which the antenna module 1000 is coupled may be implemented as a certain length Ld or less. One end portion and a rear surface of the antenna module 1000 may be coupled to a side region and a rear surface of the first cover 201, such that the antenna module 1000 is arranged parallel to a horizontal plane. A structure to be assembled or pressed may be assembled or pressed in a downward or upward direction.

Referring to (b) of FIG. 1, a support structure, such as the heat sink 204, includes a first end portion 204a, a second end portion 204b, and a third end portion 204c that are coupled to the antenna module 1000. A first hole 204d and a second hole 204e may be formed through the first end portion 204a and the second end portion 204b of the heat sink 204, respectively. In the antenna module 1000, a region where an electronic component, such as an RFIC chip, is arranged may be coupled to the third end portion 204c of the heat sink 204. Accordingly, heat generated from the electronic component, such as the RFIC chip, may be discharged to an external region through the heat sink 204.

A plurality of holes may be formed in a specific region where the radiator of the antenna module 1000 is not arranged. A first through hole 1001 and a second through hole 1002 may be formed through one side and another side of the antenna module 1000. A first screw 205a may be coupled to the first hole 204d of the heat sink 204 and the first through hole 1001 of the antenna module 1000. A second screw 205b may be coupled to the second hole 204e of the heat sink 204 and the second through hole 1002 of the antenna module 1000. Referring to FIG. 1, the antenna module 1000 may be coupled to the support structure, such as the heat sink 204, through the coupling structure of the screws and holes.

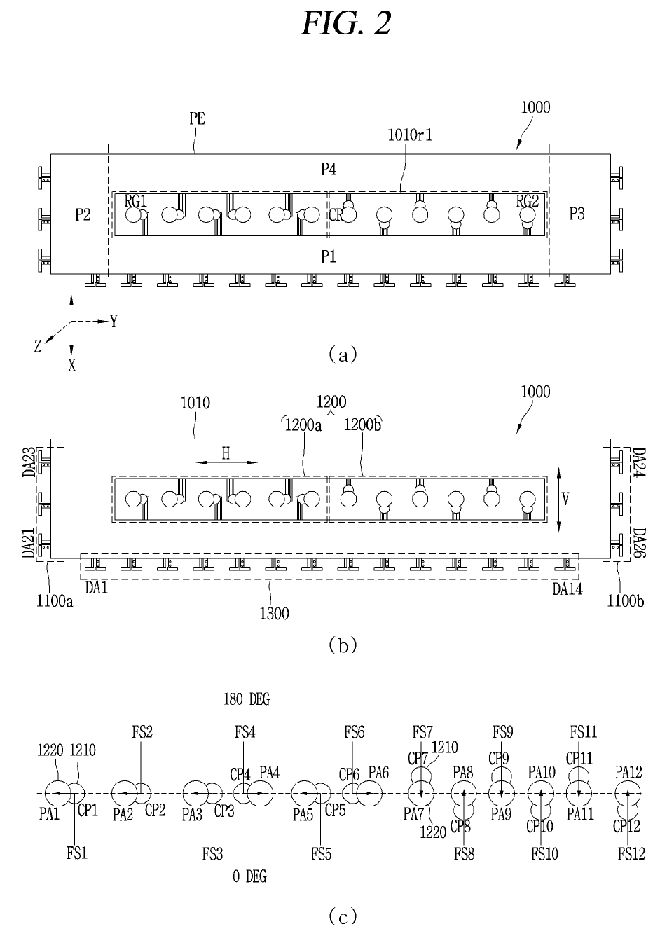

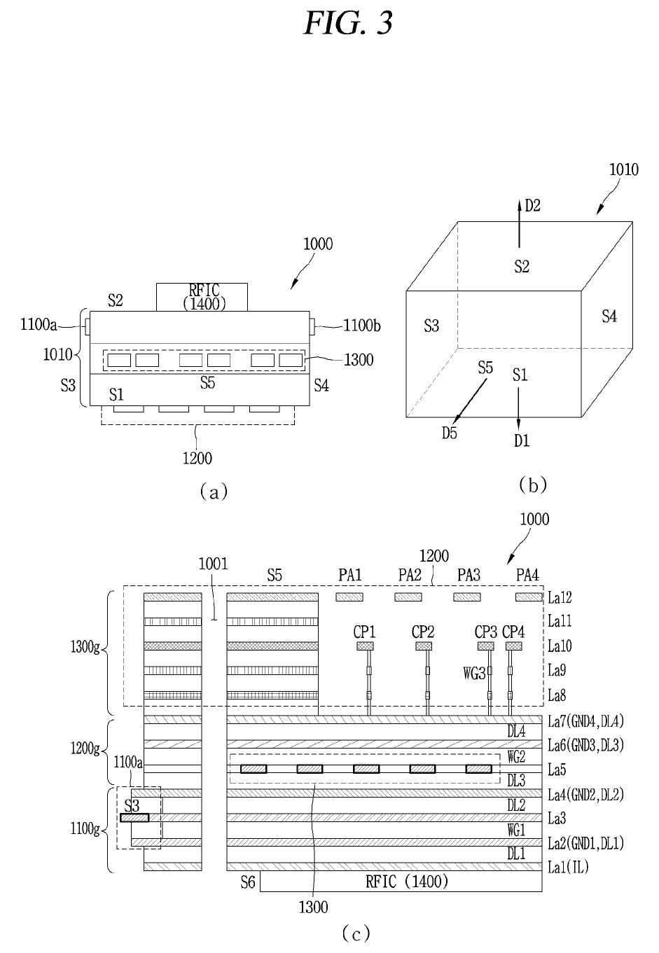

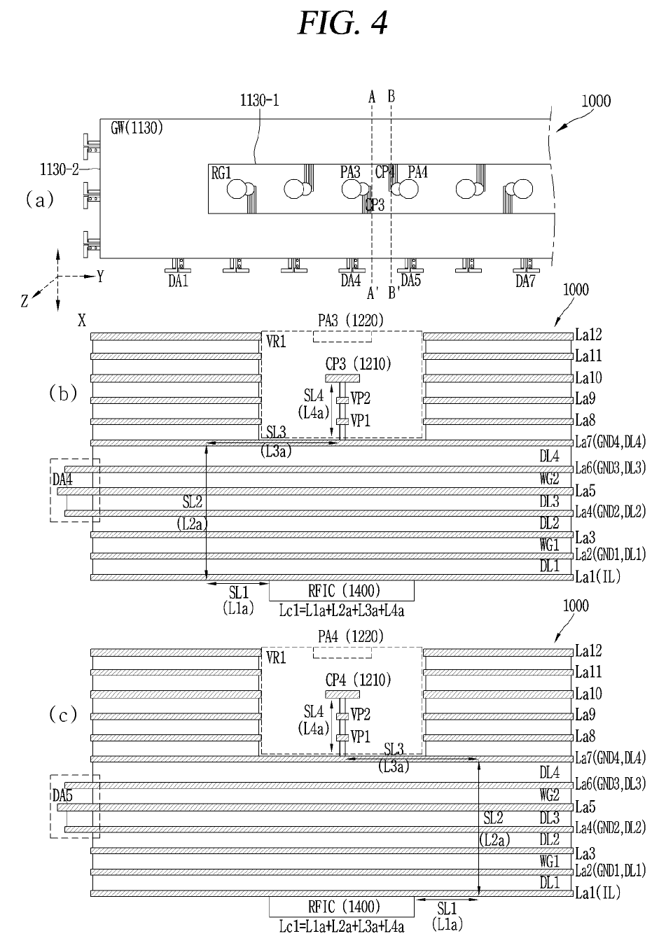

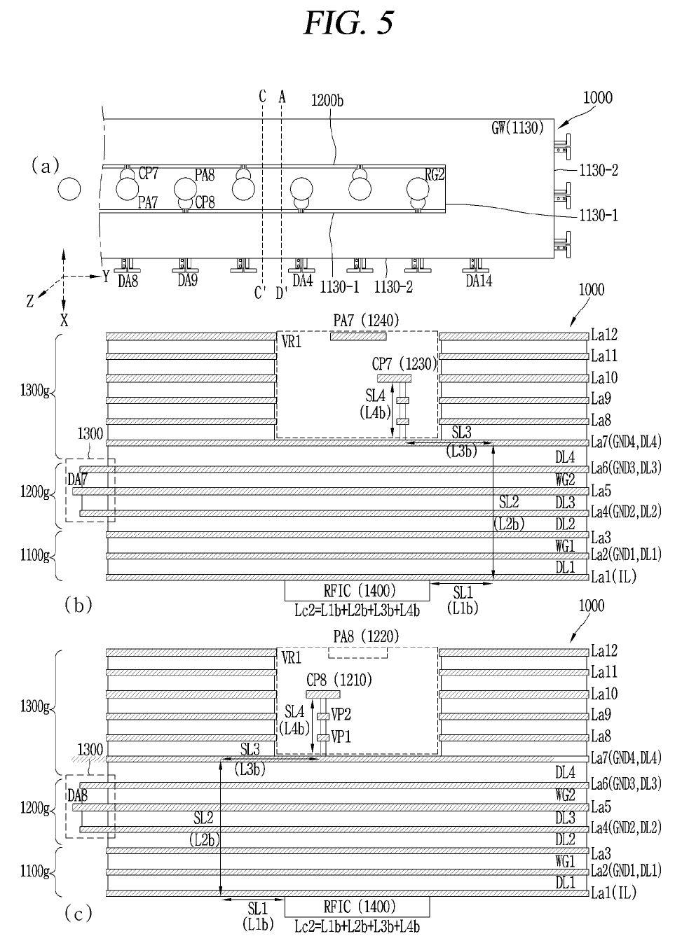

Hereinafter, an antenna module which may be arranged in an electronic device according to the disclosure will be described. In this regard, FIG. 2 is a front view of a substrate on which the antenna module is arranged. FIG. 3 shows a cross-sectional view and a three-dimensional structure of a substrate on which the antenna module of FIG. 2 is arranged. FIG. 4 shows front and cross-sectional views of a horizontal polarization antenna in a first region of the antenna module. FIG. 5 shows front and cross-sectional views of a vertical polarization antenna in a second region of the antenna module.

(a) of FIG. 2 is a view of a substrate with an antenna module 1000 for each region. (b) of FIG. 2 is a view of array antennas arranged in each region of the antenna module 1000. (c) of FIG. 2 is a view of a structure in which a feed signal is applied to some antenna elements arranged in an array antenna arrangement region.

Referring to FIG. 2, a substrate 1010 may include a central region CR and a periphery PE surrounding the central region CR. The periphery PE of the substrate 1010 may include a first part P1 through a fourth part P4. The first part P1 constitutes a lower region of the substrate 1010, and the second part P2 constitutes one side region of the substrate 1010. The third part P3 constitutes another side region of the substrate 1010, and the fourth part P4 constitutes an upper region of the substrate 1010. The antenna module 1000 may include the substrate 1010, and a phased array antenna portion 1200 arranged in an array antenna arrangement region 1010r1.

(a) of FIG. 3 is a cross-sectional view of the antenna module 1000 with a structure in which a plurality of array antennas are arranged on the substrate 1010. (b) of FIG. 3 is a view of a three-dimensional structure of the substrate 1010 having a plurality of surfaces. (c) of FIG. 3 is a cross-sectional view of the antenna module 1000 including a plurality of layers of (a) of FIG. 3.

Referring to FIG. 3, the substrate 1010 may include a first surface S1 through a sixth surface S6. An RFIC chip 1400 may be arranged on the second surface S2 of the substrate 1010. First and second array antennas 1100a and 1100b may be arranged on the third surface S3 and the fourth surface S4 of the substrate 1010. The phased array antenna portion 1200 may be arranged on the first surface S1 of the substrate 1010 to correspond to a third array antenna. A fourth array antenna 1300 may be arranged on the fifth surface S5 of the substrate 1010.

The substrate 1010 may be implemented as a printed circuit board (PCB) having a plurality of layers. The substrate 1010 may be implemented as a PCB having a first layer La1 through a twelfth layer La12. A through hole 1001 may be formed through one side of the substrate 1010.

(a) of FIG. 4 shows a first region RG1 of the antenna module 1000. (b) of FIG. 4 is a cross-sectional view taken along the line AA' of the antenna module 1000. (c) of FIG. 4 is a cross-sectional view taken along the line BB' of the antenna module 1000. (a) of FIG. 5 shows a second region RG2 of the antenna module 1000. (b) of FIG. 5 is a cross-sectional view taken along the line CC' of the antenna module 1000. (c) of FIG. 5 is a cross-sectional view taken along the line DD' of the antenna module 1000.

Referring to FIGS. 2 to 5, the first and second array antennas 1100a and 1100b may be arranged on the third surface S3 and the fourth surface S4 of the substrate 1010. The phased array antenna portion 1200 may be arranged on the first surface S1 and an inner space of the substrate 1010. The fourth array antenna 1300 may be arranged on the fifth surface S5 of the substrate 1010. A region where the fourth array antenna 1300 is arranged may form a first ground layer 1100g with a first coplanar waveguide structure. A region where the first and second array antennas 1100a and 1100b are arranged may form a second ground layer 1200g with a second coplanar waveguide structure. A region where the phased array antenna portion 1200 is arranged may form a third ground layer 1300g with a third coplanar waveguide structure.

An inner ground wall (GW) 1130-1 formed inside the PCB 1010 may operate as a ground for radiation of patch antennas PA1 to PA12 and CP1 to CP12. A ground wall (GW) 1130 functions as a reflector that suppresses side surface radiation of the patch antennas PA1 to PA12 and CP1 to CP12. An outer ground wall 1130-2 formed on an outer surface of the PCB 1010 functions as a reflector which suppresses radiation to an opposing side surface of dipole antennas DA21 to DA26 with a side surface radiation structure, and induces reflection toward the corresponding side surface. The ground wall (GW) 1130 functions as a reflector which suppresses rear surface radiation of dipole antennas DA1 to DA14 having a front surface radiation structure, and induces reflection toward the front surface.

Hereinafter, the antenna module 1000 according to the disclosure will be described with reference to FIGS. 1 to 5. The antenna module 1000 may be configured to include a substrate 1010, first to fourth array antennas 1100a, 1100b, 1200, and 1300, and an RFIC chip 1400 which is a millimeter wave transceiver circuitry.

The substrate 1010 may include a first surface S1, a second surface S2, and a periphery PE. The periphery PE may be formed between the first surface S1 and the second surface S2. The first surface S1 may be opposite to the second surface S2. A ground region and an array antenna arrangement region 1010r1 may be formed on the first surface S1. The substrate 1010 may be implemented as a multi-layer substrate. For example, the substrate 1010 may be implemented as a substrate with twelve layers, but is not limited thereto, and may vary depending on applications.

The first surface S1 may be an outermost surface of the PCB 1010. The first surface S1 may be formed of a metal layer connected to the ground. An inner surface of the metal layer corresponds to the array antenna arrangement region 1010r1 in which array antennas operating as horizontal polarization antennas, including a first patch antenna 1220 and a second patch antenna 1210, are arranged. The inner surface of the metal layer corresponds to the array antenna arrangement region 1010r1 in which array antennas operating as vertical polarization antennas, including a third patch antenna 1240 and a fourth patch antenna 1230, are arranged.

The first surface S1 of the substrate 1010 is divided into a central region CR, a first part P1, a second part P2, a third part P3, and a fourth part P4. The second part P1 may be located on the left side of the first part P1 and the third part P3 is located on the right side of the first part P1. The second part P2 is located on the left side of the fourth part P4 and the third part P3 is located on the right side of the fourth part P4. A ground region is arranged on the first part P1 to the first part P1 to the fourth part P4. The array antenna arrangement region 1010r1 is formed in the central region CR, which is surrounded by the first part P1 to the fourth part P4.

The first array antenna 1100a is arranged in an outer peripheral (PE) region of the second part P2. The second array antenna 1100b is arranged in an outer peripheral (PE) region of the third part P3. The first array antenna 1100a and the second array antenna 1100b may form beam patterns to side regions of the electronic device. The first array antenna 1100a and the second array antenna 1100b may radiate horizontally polarized signals to the side regions of the electronic device.

The first array antenna 1100a may include a plurality of dipole antennas DA21 to DA23. The second array antenna 1100b may include a plurality of dipole antennas DA24 to DA26. The first array antenna 1100a and the second array antenna 1100b may each be implemented to include three antenna elements on one side and another side of the periphery PE of the substrate 1010a. The first array antenna 1100a may be implemented as a 1x3 array antenna on the one side of the substrate 1010, but is not limited thereto. The second array antenna 1100b may be implemented as a 1x3 array antenna on the another side of the substrate 1010, but is not limited thereto.

The phased array antenna portion 1200 may be arranged on the first surface S1 of the substrate 1010. The phased array antenna portion 1200 may generate a beam pattern toward the lower region of the electronic device. The phased array antenna portion 1200 may radiate a vertically polarized signal to the lower region of the electronic device. The phased array antenna portion 1200 may be implemented to include twelve antenna elements on the central region CR of the substrate 1010.

The phased array antenna portion 1200 may include a plurality of first patch antennas PA1 to PA12 arranged on the first surface S1 of the substrate 1010. The phased array antenna portion 1200 may be implemented as a 1x12 array antenna on the central region CR of the substrate 1010, but is not limited thereto.

Each patch antenna in the first region RG1 of the phased array antenna portion 1200 may include the first patch antenna 1220 and the second patch antenna 1210. The second patch antenna 1210 may be stacked in a Z-axis direction, which is a height direction, on the first patch antenna 1220 such that a signal of the first patch antenna 1220 is coupled. The center of the second patch antenna 1210 may be offset with respect to the center of the first patch antenna 1220 in a Y-axis direction which is a horizontal axis direction.

Each patch antenna in the second region RG2 of the phased array antenna portion 1200 may include the third patch antenna 1240 and the fourth patch antenna 1230. The fourth patch antenna 1230 may be stacked in the Z-axis direction, which is the height direction, on the third patch antenna 1240 such that a signal of the third patch antenna 1240 is coupled. The center of the fourth patch antenna 1230 may be offset with respect to the center of the third patch antenna 1240 in an X-axis direction which is a vertical axis direction.

In this regard, the second patch antennas 1210 in first, second, third, and fifth columns may be offset to a right region with respect to the first patch antennas 1220 based on the Y-axis. The second patch antennas 1210 in fourth and sixth columns may be offset to a left region with respect to the first patch antennas 1220 based on the Y-axis. Accordingly, the second patch antennas 1210 in the third to sixth columns can be alternately offset in different directions with respect to the first patch antennas 1220 in the third to sixth columns. In another example, the second patch antennas 1210 in first and second columns may be offset in the same direction with respect to the first patch antennas 1220 in first and second columns.

A current direction of signals applied to the second patch antennas 1210 in the first, second, third, and fifth columns is from right to left. A current direction of signals applied to the second patch antennas 1210 in the fourth and sixth columns is from left to right. Accordingly, the current direction of the signals applied to the second patch antennas 1210, which are alternately offset in the different directions, is opposite to the current direction of the signals applied to the corresponding first patch antennas 1220. Therefore, a phase difference between the signals applied to the alternately offset second patch antennas 1210 must be 180 degrees, so that a current in the same direction can be formed. To this end, the RFIC chip 1400 may control a phase shifter such that the phase difference between the signals applied to the alternately offset second patch antennas 1210 is 180 degrees.

In this regard, a third feed signal FS3 may be applied to a coupling patch CP3, which is the second patch antenna 1210 in the third column. A fourth feed signal FS4 may be applied to a coupling patch CP4, which is the second patch antenna 1210 in the fourth column. In case that the third and fourth feed signals FS3 and FS4 are in-phase signals, electric fields may be formed in opposite directions in the coupling patches CP3 and CP4. A directional beam may be formed only when the electric fields are generated in the same direction by the coupling patches CP3 and CP4. To this end, it is necessary to make the phase difference between the third feed signal FS3 and the fourth feed signal FS4 180 degrees. Likewise, it is necessary to make a phase difference between a fifth feed signal FS5 and a sixth feed signal FS6 180 degrees. In another example, a first feed signal FS1 and a second feed signal FS2 need to be formed as in-phase signals.

Accordingly, each of the first, second, third, and fifth feed signals FS1, FS2, FS3, and FS5 applied to the coupling patches CP1, CP2, CP3, and CP5, which are the second patch antennas 1210 in the first, second, third, and fifth columns, has a first phase value. In some embodiments, each of the fourth and sixth feed signals FS4 and FS6 applied to the coupling patches CP4 and CP6, which are the second patch antennas 1210 in the fourth and sixth columns, has a second phase value with a phase difference of 180 degrees from the first phase value.

The fourth patch antennas 1230 in seventh, ninth, and eleventh columns may be offset to the upper region with respect to the third patch antennas 1240 based on the X-axis. The fourth patch antennas 1230 in eighth, tenth, and twelfth columns may be offset to the left region with respect to the third patch antennas 1240 based on the X-axis. Accordingly, the second patch antennas 1210 may alternately be offset in different directions with respect to the first patch antennas 1220.

A current direction of signals applied to the fourth patch antennas 1230 in the seventh, ninth, and eleventh columns is from top to bottom. A current direction of signals applied to the fourth patch antennas 1230 in the eighth, tenth, and twelfth columns is from bottom to top. Accordingly, the current direction of the signals applied to the fourth patch antennas 1230, which are alternately offset in different directions, is opposite to the current direction of the signals applied to the corresponding third patch antennas 1240. Therefore, a phase difference between the signals applied to the alternately offset fourth patch antennas 1230 must be 180 degrees, so that a current in the same direction can be formed. To this end, the RFIC chip 1400 may control a phase shifter such that the phase difference between the signals applied to the alternately offset fourth patch antennas 1230 is 180 degrees.

In this regard, a seventh feed signal FS7 may be applied to a coupling patch CP7, which is the fourth patch antenna 1230 in the seventh column. An eighth feed signal FS8 may be applied to a coupling patch CP8, which is the fourth patch antenna 1230 in the eighth column. In case that the seventh and eighth feed signals FS7 and FS8 are in-phase signals, electric fields may be formed in opposite directions in the coupling patches CP7 and CP8. A directional beam may be formed only when the electric fields are generated in the same direction by the coupling patches CP7 and CP8. To this end, it is necessary to make the phase difference between the seventh feed signal FS7 and the eighth feed signal FS8 180 degrees. Likewise, it is necessary to make a phase difference between a ninth feed signal FS9 and a tenth feed signal FS10 180 degrees. It is also necessary to make a phase difference between an eleventh feed signal FS11 and a twelfth feed signal FS12 180 degrees.

Accordingly, each of the seventh, ninth, and eleventh feed signals FS7, FS9, and FS11 applied to the coupling patches CP7, CP9, and CP11, which are the fourth patch antennas 1230 in the seventh, ninth, and eleventh columns, has a first phase value. In some embodiments, each of the eighth, tenth, and twelfth feed signals FS8, FS10, and FS12 applied to the coupling patches CP8, CP10, and CP12, which are the fourth patch antennas 1230 in the eighth, tenth, and twelfth columns, has a second phase value with a phase difference of 180 degrees from the first phase value.

The fourth array antenna 1300 may be arranged on the first part P1 of the periphery PE of the substrate 1010. The fourth array antenna 1300 may form a beam pattern toward the front region of the electronic device. The fourth array antenna 1300 may radiate a horizontally polarized signal to the front region of the electronic device.

The fourth array antenna 1300 may include a plurality of dipole antennas DA1 to DA14 arranged on the first part P1 of the periphery PE of the substrate 1010. The fourth array antenna 1300 may be implemented to include 14 antenna elements on the lower side of the periphery PE of the substrate 1010. The fourth array antenna 1300 may be implemented as a 1x14 array antenna on the lower side of the periphery PE of the substrate 1010, but is not limited thereto.

The RFIC chip 1400 may be configured to transmit and receive signals at frequencies between 10 GHz and 400 GHz using at least one of the first and second array antennas 1100a and 1100b, the phased array antenna portion 1200, and the fourth array antenna 1300. The RFIC chip 1400 may be configured to transmit and receive signals at frequencies between 10 GHz and 400 GHz using at least one of the plurality of dipole antennas DA21 to DA26, the plurality of patch antennas PA1 to PA12 and CP1 to CP12, and the plurality of dipole antennas DA1 to DA14. The RFIC chip 1400 may be referred to as a radio frequency integrated chip.

The number of elements of the fourth array antenna 1300 forming the beam pattern toward the front region may be set to be greater than the number of elements of the phased array antenna portion 1200 forming the beam pattern toward the lower region. The number of elements of the phased array antenna portion 1200 forming the beam pattern toward the lower region may be set to be greater than the number of elements of the first and second array antennas 1100a and 1100b forming the beam patterns toward the side regions.

In this regard, 12 pins among 32 pins of the RFIC chip 1400 may be connected to the phased array antenna portion 1200 forming the beam pattern toward the lower region. 14 pins among the 32 pins of the RFIC chip 1400 may be connected to the fourth array antenna 1300 forming the beam pattern toward the front region. 6 pins among the 32 pins of the RFIC chip 1400 may be connected to the first and second array antennas 1100a and 1100b forming the beam patterns toward the side regions.

In this regard, the fourth array antenna 1300 has the largest number of elements, and thus can transmit signals over a long distance to the front region of the electronic device, but has a narrow beam coverage. The narrow beam coverage can be supplemented by changing a beam direction to a horizontal direction of the front region through beamforming. The fourth array antenna 1300 may include a plurality of elements implemented in the Y-axis direction and one element implemented in the Z-axis direction. For example, the fourth array antenna 1300 may be implemented as a 1x14 array antenna.

The electronic device needs to perform wireless communication with another electronic device arranged in the lower region thereof. For wireless communication, beamforming may be implemented in narrow beam coverage units in the lower region of the electronic device in a horizontal direction, which is the Y-axis direction. In some embodiments, the lower region of the electronic device does not require a signal transmission over a long distance, compared to the front region. The phased array antenna portion 1200 may include a plurality of elements implemented in one axial direction and one element implemented in another axial direction. For example, the phased array antenna portion 1200 may be implemented as a 1x8, 1x10, or 1x12 array antenna.

Signals may also be transferred to the side regions of the electronic device in an indoor radio wave environment where the electronic device is arranged. It is more important to implement a wide beam coverage for the side regions of the electronic device even without beamforming, than to implement a signal transmission over a long distance. In this regard, the first and second array antennas 1100a and 1100b may each have the smallest number of elements, and thus can implement a wide beam coverage to the side regions of the electronic device. Accordingly, the first and second array antennas 1100a and 1100b may include a plurality of elements in the one axial direction and one element in the another axial direction. For example, the first and second array antennas 1100a and 1100b may be implemented as 1x3 array antennas on one side and another side.

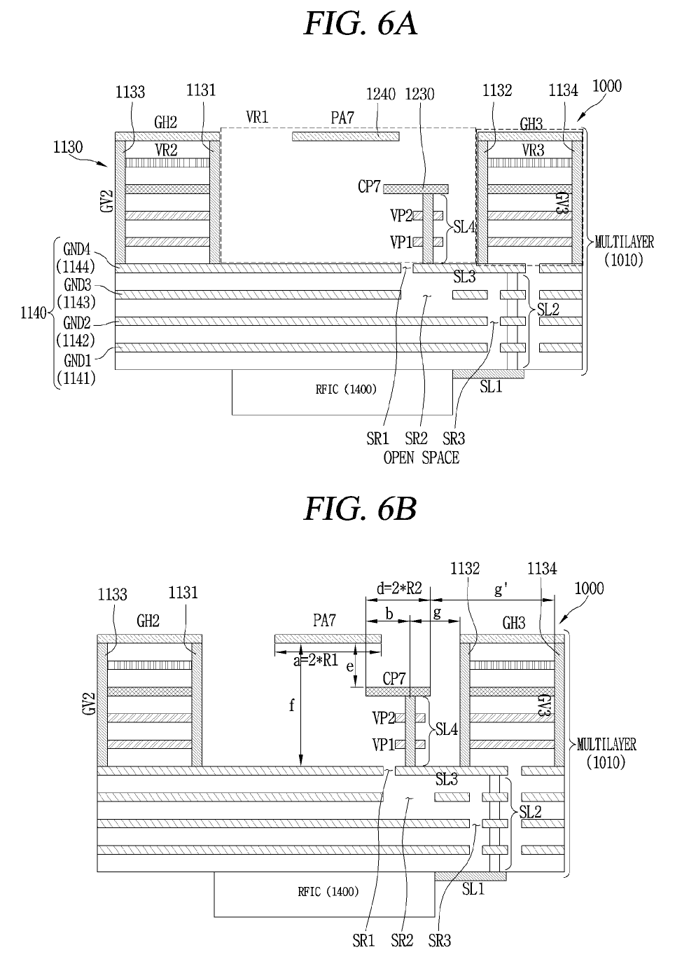

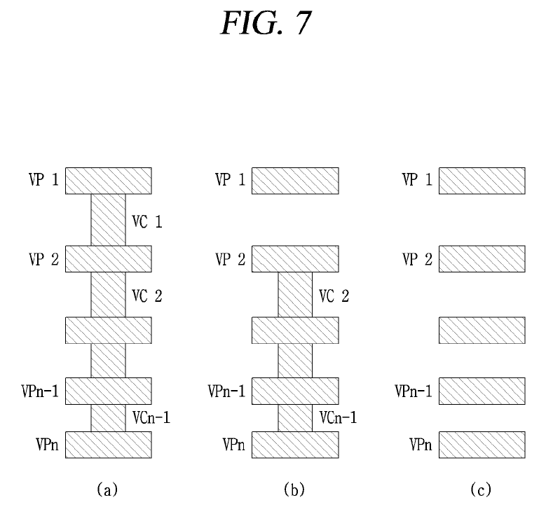

In some embodiments, the patch antennas of the phased array antenna portion 1200 according to the disclosure may be stacked so that partial regions overlap. In this regard, FIG. 6A is a lateral view of a partial region of the antenna module with patch antennas having an overlap structure, shown in FIG. 5. FIG. 6B is a view showing sizes and gaps of radiators arranged on different layers and gaps between the radiators and a ground wall in the lateral view of the antenna module of FIG. 6A.

Referring to FIGS. 5 and 6, the third patch antenna 1240 and the fourth patch antenna 1230 may be arranged in a first vertical region VR1. The fourth patch antenna 1230 is connected to a fourth part SL4 of signal connection lines SL1 to SL4. The third patch antenna 1240 may be arranged in the upper region of the fourth patch antenna 1230 to be offset to one side, such that a signal transmitted to the fourth patch antenna 1230 is coupled to the third patch antenna 1240.

Referring to FIGS. 5 to 6B, the third patch antenna 1240 may have a length of d=2*R1 in one axial direction. The fourth patch antenna 1230 may have a length of d=2*R2 in the one axial direction. A distance b from one end of the fourth patch antenna 1230 to a point connected to the fourth part SL4 of the plurality of signal connection lines may be set to a value of R2<b<d. In this regard, a feed connection region of the fourth patch antenna 1230 may be offset from the center of the fourth patch antenna 1230 in the one axial direction. A distance g from the feed connection region of the fourth patch antenna 1230 to a horizontal ground wall GH3 may be at least a certain gap such that the characteristic change for each operating frequency is below a threshold. A distance g' from another end of the fourth patch antenna 1230 to a vertical ground wall GV3 may be at least a certain gap such that the characteristic change for each operating frequency is below a threshold.

Hereinafter, the antenna module 1000 including the plurality of layers according to the disclosure will be described, with reference to FIGS. 4 to 6B. In the antenna module 1000 disclosed herein, the fourth part SL4 connected to the fourth patch antenna 1230 may be arranged in a dielectric region. In this case, a signal via corresponding to the fourth part SL4 may be arranged in the dielectric region not to be electrically connected to a fourth ground layer GND4. In this regard, a slot region SR1 may be formed on the fourth ground layer GND4.

The antenna module 1000 may include at least one lower conductive layer below a fourth lower conductive layer 1144 which corresponds to the fourth ground layer GND4. In this regard, the antenna module 1000 may include a fourth lower conductive layer 1144 and a third lower conductive layer 1143 arranged below the fourth lower conductive layer 1144. The third lower conductive layer 1143 may be arranged on the same layer as a third part SL3 with being spaced apart from one end and another end of the third part SL3. Therefore, the plurality of lower conductive layers 1140 may include the third lower conductive layer 1143 and the fourth lower conductive layer 1144.

In some embodiments, one end of the third part SL3 and one end of the lower conductive layer 1143 may be points inside the lower region of the fourth patch antenna 1230. In this regard, a region, from which a conductive layer has been removed, between the one end of the third part SL3 and the one end of the third lower conductive layer 1143 may also be referred to as a second slot region SR2. The second lower conductive layer 1143 may be electrically connected to the fourth ground layer GND4 to be implemented as a ground layer. In another example, the third lower conductive layer 1143 may be electrically disconnected from the fourth ground layer GND4 to be implemented as a signal line.

On the other hand, the antenna module 1000 may further include a second lower conductive layer 1142 which is arranged below the third part SL3 which is a feed line. The fourth ground layer GND4 above the third lower conductive layer 1143 may also be referred to as the fourth lower conductive layer. The ground layer below the third lower conductive layer 1143 may also be referred to as the second lower conductive layer. Therefore, the plurality of lower conductive layers 1140 may include the first lower conductive layer 1141, the second lower conductive layer 1142, and the third lower conductive layer 1143.

The second lower conductive layer 1142 may include a third slot region SR3, from which a conductive layer has been removed, in a region corresponding to the lower region of the fourth patch antenna 1230. A length of the third slot region SR3 on one axis may be longer than lengths of a plurality of pads of the fourth part SL4 as the signal via on one axis. Therefore, the third slot region SR3, from which the conductive layer has been removed, is formed in a second ground layer GND2 below a point where the fourth part SL4 connected to the fourth patch antenna 1230 is connected to the third part SL3.

Regions, such as the slot regions SR1 to SR3, from which the conductive layer has been removed, may be referred to as open spaces. The open spaces, such as the slot regions SR1 to SR3, may lower a resonating frequency of an antenna to a low frequency band without increasing the size of the patch antenna. Therefore, the ground region can be partially removed, and thus an entire height of the antenna can increase such that the antenna can operate as a broadband antenna.

The plurality of lower conductive layers 1140 may include the first lower conductive layer 1141, the second lower conductive layer 1142, the third lower conductive layer 1143, and the fourth lower conductive layer 1144. The first lower conductive layer 1141 may be arranged adjacent to a pad of the second part SL2 to cover a lower region of a portion where the fourth patch antenna 1230 is arranged. The first lower conductive layer 1141 may be implemented as a ground layer. In some embodiments, depending on an application, the first lower conductive layer 1141 may also be implemented as a conductive layer which floats without being electrically connected to a ground layer. The first lower conductive layer 1141 may be implemented as a plurality of conductive layers which are separated from one another. Some of those conductive layers may operate as ground layers and the others may operate as conductive layers in a floating state.

In some embodiments, the antenna module 1000 may further include vertical ground walls 1131 to 1134 arranged on the fourth conductive layer GND4 and each having a plurality of pads. The third patch antenna 1240 and the fourth patch antenna 1230 may be stacked in a space between the vertical ground walls 1131 and 1132 to partially overlap each other.

Patch antennas stacked on different layers of the antenna module 1000 according to the disclosure to have an overlap region may be arranged in a space formed by the ground wall 1130. Referring to FIGS. 4 to 6B, the ground wall 1130 may be formed along side regions of the substrate 1010 having the plurality of layers. In this regard, the ground wall 1130 may include conductive pads arranged on the plurality of layers, and vias connecting the conductive pads. The ground wall 1130 including the conductive pads and vias may be referred to as a ground via wall.

The ground wall 1130 may include a first ground wall 1131 formed along one side of a first vertical region VR1, and a second ground wall 1132 formed along another side of the first vertical region VR1. The ground wall 1130 may further include a third ground wall 1133 formed along one side of a second vertical region VR2, and a fourth ground wall 1134 formed along one side of a third vertical region VR3.

The ground wall 1130 may be arranged on an edge of the substrate 1010 and an edge of the array antenna arrangement region 1010r1 with respect to the third patch antenna 1240. The ground wall 1130 may be arranged on at least one of upper, lower, left, and right sides based on the third patch antenna 1240. The ground wall 1130 may be connected to the ground layer to improve an antenna gain. In another example, the ground wall 1130 may be configured as a floating conductive wall which merely includes via pads without vertical connection portions.

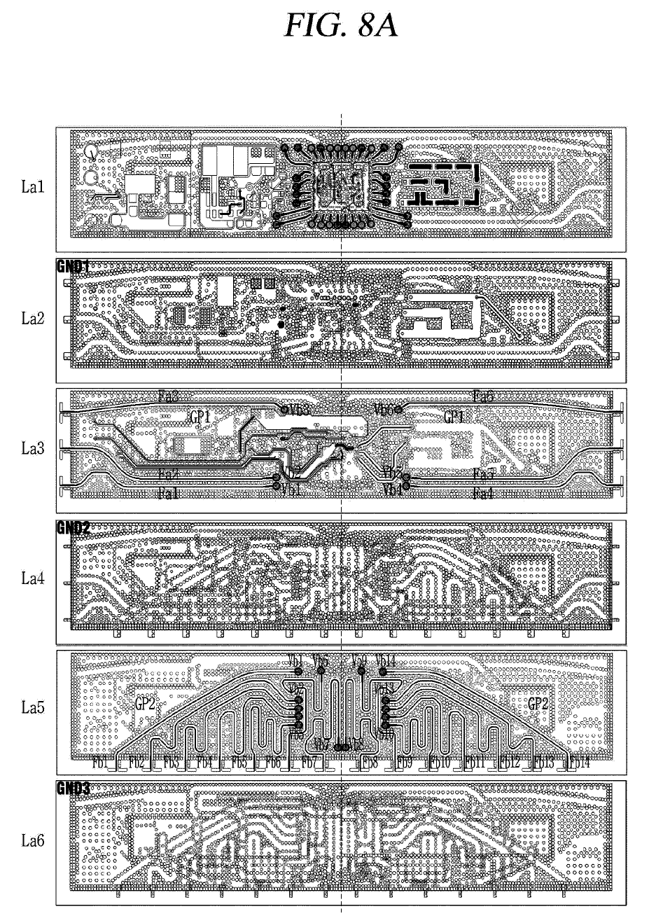

In this regard, FIG. 7 is a view of via wall formation structures according to various embodiments. Referring to FIG. 7, a via wall may configure signal connection lines or connect ground planes. Via pads VP1 to VPn in the form of thin film may be arranged on all the layers of the substrate 1010, but, in some examples, may be arranged only on several layers.

Referring to (a) and (b) of FIG. 7, the ground wall may include vertical connection portions VC1, VC2, ..., VCn-1, and a plurality of pads VP1, VP2, ..., VPn. Referring to (a) of FIG. 7, adjacent pads of the plurality of pads VP1, VP2, ..., VPn may be interconnected by one of the vertical connection portions VC1, VC2, ..., VCn-1. On the other hand, referring to (b) FIG. 7, at least one adjacent pad of the plurality of pads VP1, VP2, ..., VPn of the ground wall 1130 may not be connected by a vertical connection portion.

As one example, the first pad VP1 and the second pad VP2 may be coupled without a vertical connection portion and the other pads may be connected by the vertical connection portions VC2 to VCn-1. However, with no limit thereto, the pads may be connected or may not be connected for each layer. In this regard, for example, when signal lines are arranged in a region adjacent to the via wall, the via wall may be coupled without a vertical connection portion. Upon the coupling without the vertical connection portion, a plurality of conductive layers may form an electronic band gap (EBG) structure without being electrically connected to the ground layer. This can reduce interference due to an adjacent radiator or signal line or suppress deformation due to pressure or heat applied to the substrate 1010.

In another example, referring to (c) of FIG. 7, the plurality of pads VP1, VP2, ..., VPn of the ground wall 1130 may be coupled without vertical connection portions. Accordingly, vertical ground walls GV1 to GV5 of FIGS. 4 to 6B may be implemented as any one structure of the ground walls shown in (a) to (c) of FIG. 7.

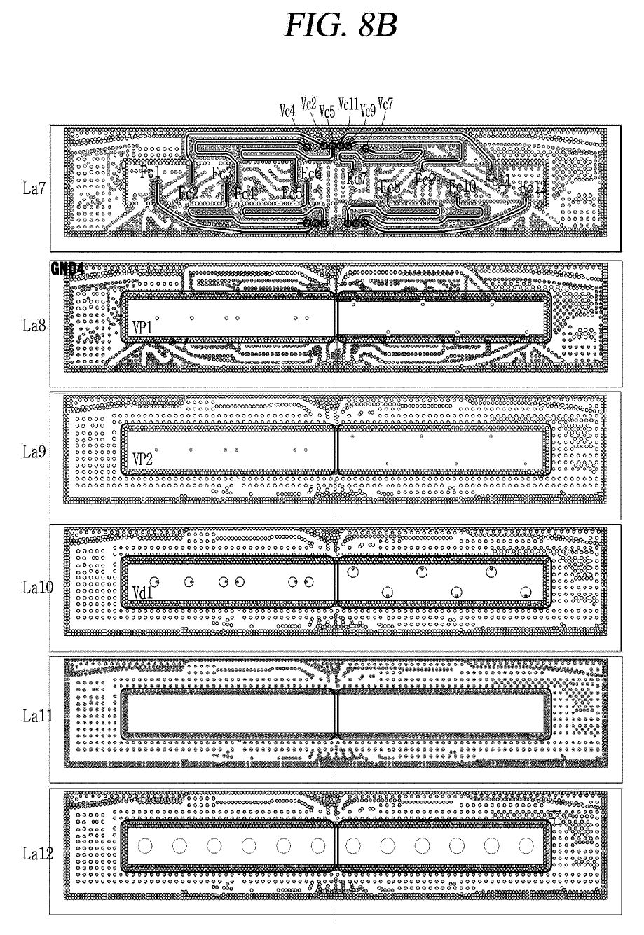

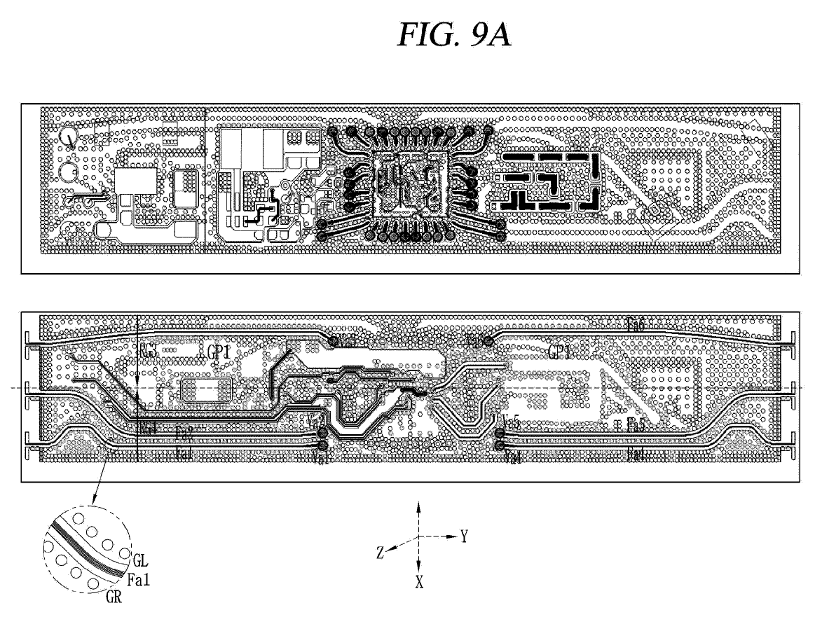

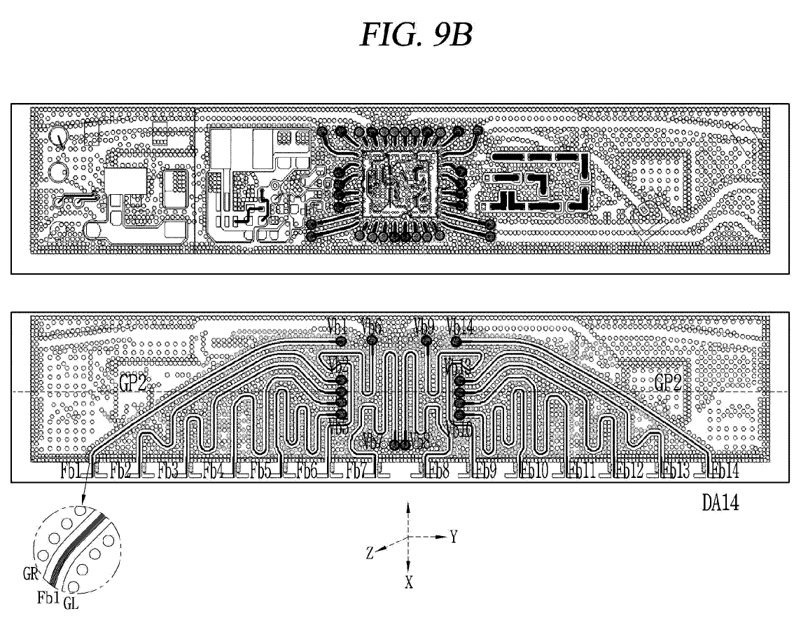

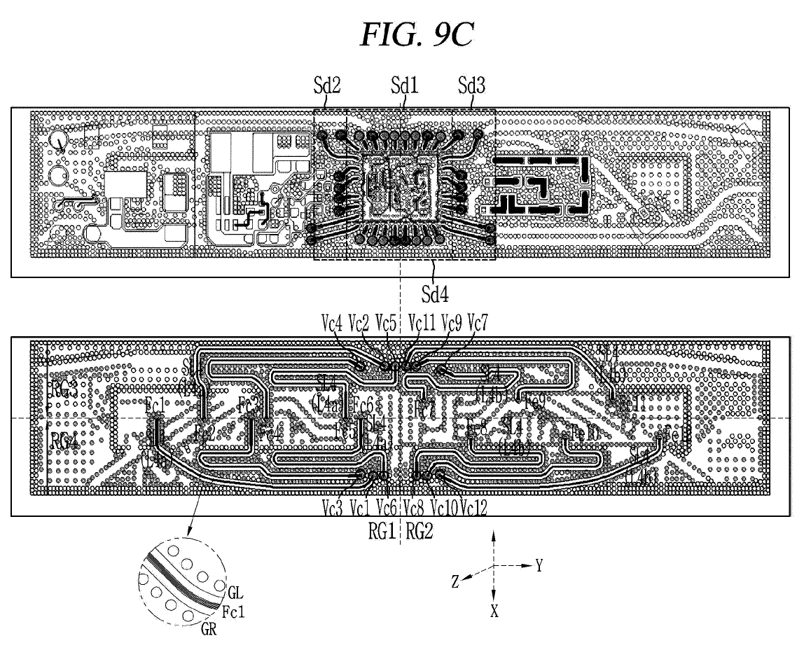

Hereinafter, an arrangement structure for each layer of the antenna module according to the disclosure will be described. In this regard, FIGS. 8A and 8B are front views showing the antenna modules of FIGS. 4 and 5 for each layer. FIG. 9A is a view of first and third layers of the antenna module of FIG. 8A. FIG. 9B is a view of first and fifth layers of the antenna module of FIG. 8A. FIG. 9C is a view of first and seventh layers of the antenna module of FIGS. 8A and 8B.

Hereinafter, each layer of the antenna module 1000 will be described in detail with reference to FIGS. 2 to 8C. The antenna module 1000 may be configured by stacking a first layer La1, on which the transceiver circuitry 1400 is arranged, through a fifth layer La5 and a sixth layer La6, on which feed lines for the fourth array antenna 1300 are located. The antenna module 1000 may further include a seventh layer La7, on which the feed lines for the phased array antenna portion 1200 are arranged, through a twelfth layer La12, on which antenna elements of the phased array antenna portion 1200 are arranged.

The transceiver circuitry 1400 may be arranged on the first layer La1. The transceiver circuitry 1400 may have a plurality of pins, and signal connection lines may be connected to the plurality of pins. The transceiver circuitry 1400 may be arranged based on a center line of the first layer La1 in one axial direction.

The second layer La2 may include a metal layer, so as to be configured as a first ground layer GND1 for the first layer La1. The dipole antennas DA21 to DA26 of the first and second array antennas 1100a and 1100b may be arranged on one side region and another side region of the third layer La3. End portions of first feed lines Fa1 to Fa6 of the dipole antennas DA21 to DA26 may be connected to signal connection lines of the first layer La1 by first vias Va1 to Va6. Each of the first feed lines Fa1 to Fa6 may include ground patterns GL and GR, which are formed on one side and another side thereof and have vias, respectively, thereby forming a first ground part GP1. Accordingly, the first feed lines Fa1 to Fa6 may be formed in a coplanar waveguide structure.

The fourth layer La4 may include a metal layer so as to be configured as a second ground layer GND2 for the third layer La3. The first feed lines Fa1 to Fa6 of the third layer La3 are arranged between the ground layer of the second layer La2 and the ground layer of the fourth layer La4. Accordingly, the first feed lines Fa1 to Fa6 of the third layer La3 constitute a first coplanar waveguide structure in which the ground layers are arranged on an upper layer and a lower layer in a heightwise direction. The metal layers of the ground layer of the second layer La2 and the ground layer of the fourth layer La4 may be partially removed so that the first vias can be vertically connected.

The dipole antennas DA1 to DA14 of the fourth array antenna 1300 may be arranged in a lower region of the fifth layer La5 on an XY plane. End portions of second feed lines Fb1 to Fb14 of the dipole antennas DA1 to DA14 may be connected to lines of the first layer La1 by second vias Vb1 to Vb14.

The sixth layer La6 may include a metal layer so as to be configured as a ground layer GND3 for the fifth layer La5. The second feed lines of the fifth layer La5 are arranged between the ground layer of the fourth layer La4 and the ground layer of the sixth layer La6. Accordingly, the second feed lines of the fifth layer La5 constitute a second coplanar waveguide structure in which the ground layers are arranged on an upper layer and a lower layer in a heightwise direction. The metal layers of the ground layer of the fourth layer La4 and the ground layer of the sixth layer La6 may be partially removed so that the first and second vias can be vertically connected.

On the seventh layer La7, third feed lines for the second patch antennas CP1 to CP12 of the phased array antenna portion 1200 may be arranged. Each of the third feed lines may have the same distance between opposite end portions thereof. The third feed lines may be electrically connected to lines of the first layer La1 by third vias Vc1 to Vc12 that are formed on one end portions of the third feed lines.

The eighth layer La8 may include a metal layer so as to be configured as the fourth ground layer GND4. The third feed lines of the seventh layer La7 are arranged between the ground layer of the sixth layer La6 and the ground layer of the eighth layer La8. Accordingly, the third feed lines of the seventh layer La7 constitute a third coplanar waveguide structure in which the ground layers are arranged on an upper layer and a lower layer in a heightwise direction. The metal layers arranged in the ground layer of the sixth layer La6 and the ground layer of the eighth layer La8 may be partially removed so that the second and third vias can be vertically connected.

As described above, the second, fourth, sixth, and eighth layers La2, La4, La6, and La8 may configure the first to fourth ground layers GND1 to GND4, respectively. Connection vias may be arranged between the ground layers to electrically connect the ground layers. The substrate 1010 may include the first ground layer GND1 for the transceiver circuitry 1400 through the fourth ground layer GND4 for the phased array antenna portion 1200. The first and second array antennas 1100a and 1100b may be configured such that an antenna and signal lines are arranged on a layer between the first ground layer GND1 and the second ground layer GND2.

The phased array antenna portion 1200 may be configured such that an antenna and signal lines are arranged on the upper layer of the fourth ground layer GND4. The fourth array antenna 1300 may be configured such that an antenna and signal lines are arranged between the metal layer as the ground layer of the fourth layer La4 and the metal layer as the ground layer of the sixth layer La6. Accordingly, the signal lines of the first and second array antennas 1100a and 1100b, the phased array antenna portion 1200, and the fourth array antenna 1300 may be isolated by the second to fourth ground layers GND2 to GND4. This can reduce interference between the adjacent signal lines of the array antennas, which are isolated from each other by the second to fourth ground layers GND2 to GND4.

In the RFIC chip 1400, lengths of the feed lines of the phased array antenna portion 1200 may be the same for all antenna elements. The lengths of the feed lines of the phased array antenna portion 1200 may be determined as the sum of a first length L1a through a fourth length L4a.

Each of the plurality of signal connection lines SL1 to SL4 may be connected to second patch antennas CP1 to CP6 inside the PCB 1010. The lengths of the plurality of signal connection lines SL1 to SL4 may correspond to first connection lengths Lc1 between the RFIC chip 1400 and the second patch antennas CP1 to CP6. The first connection lengths Lc1 of the plurality of signal connection lines SL1 to SL4 may be the same with respect to the respective second patch antennas CP1 to CP6. Accordingly, signals applied from the RFIC chip 1400 to all the second patch antennas CP1 to CP6 can be in phase, and beams can be formed toward a center point.

Each of the plurality of signal connection lines SL1 to SL4 may be connected to fourth patch antennas CP7 to CP12 inside the PCB 1010. The lengths of the plurality of signal connection lines SL1 to SL4 may correspond to second connection lengths Lc2 between the RFIC chip 1400 and the fourth patch antennas CP7 to CP12. The second connection lengths Lc2 of the plurality of signal connection lines SL1 to SL4 may be the same with respect to the respective fourth patch antennas CP7 to CP12. Accordingly, signals applied from the RFIC chip 1400 to all the fourth patch antennas CP7 to CP12 can be in phase, and beams can be formed toward a center point.

The first connection length Lc1 may be formed by the sum of the first length L1a of the first part SL1, the second length L2a of the second part SL2, the third length L3a of the third part SL3, and the first length L4a of the fourth part SL4. The second connection length Lc2 may be formed by the sum of the first length L1b of the first part SL1, the second length L2b of the second part SL2, the third length L3b of the third part SL1, and the first length L4b of the fourth part SL1. The second connection length Lc2 may be formed to be the same as the first connection length Lc1. As another example, the second connection length Lc2 may be formed differently from the first connection length Lc1.

The third vias Vc1 to Vc12 are vertically connected from the first layer La1 to the seventh layer La7. The eighth layer La8 to the twelfth layer La12 may include a ground region which includes a metal layer, and an array antenna arrangement region 1010r1 as a first dielectric region, from which the metal layer has been removed. The coupling patches CP1 to CP12 connected to ends of third vias Vc1 to Vc12 may be arranged on the tenth layer La10. The coupling patches CP1 to CP12 may be referred to as feed plates.

The ground regions including the metal layers, which are formed on the first to twelfth layers La1 to La12, are connected by a plurality of vias. The coupling patches CP1 to CP12 of the third array antenna may be arranged on the tenth layer La10.

A metal layer forming the ground wall GW may be partially arranged on the eleventh layer La11. Second and third dielectric regions, from which the metal layers operating as the grounds have been removed, may be formed in the upper and lower regions of the eleventh layer La11. Dummy patterns may be arranged inside the second and third dielectric regions.

The tenth layer La10 to the twelfth layer La12 may further include the ground region including the metal layer, and the second dielectric region and the third dielectric region, from which the metal layer has been removed. The second and third dielectric regions may correspond to first and second dummy array pattern regions.

The first patch antennas PA1 to PA12 of the phased array antenna portion 1200 may be arranged on the twelfth layer La12. Adjacent antennas among the first patch antennas PA1 to PA12 may be arranged at the same gap. The centers of the second patch antennas CP1 to CP12 may be offset with respect to the centers of the first patch antennas PA1 to PA12 in the X-axis direction, which is the vertical axis direction.

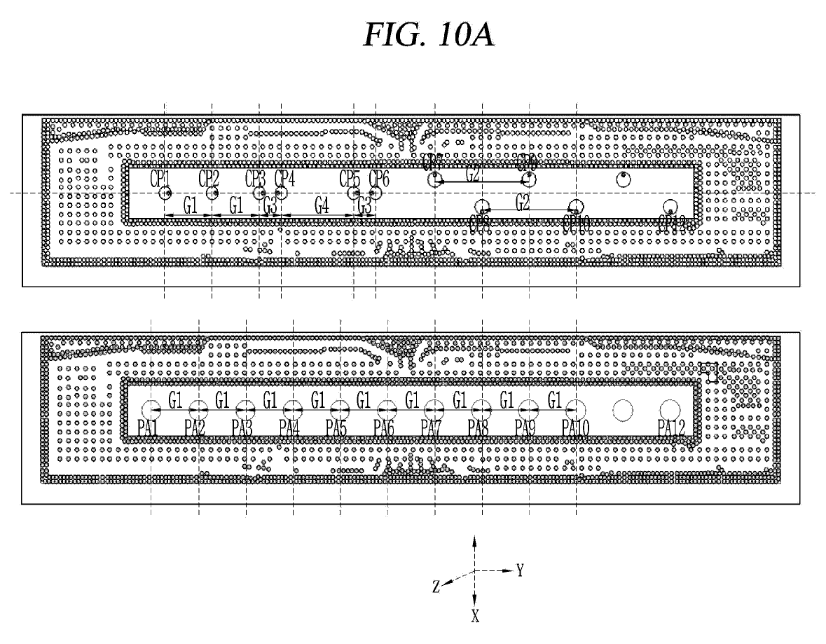

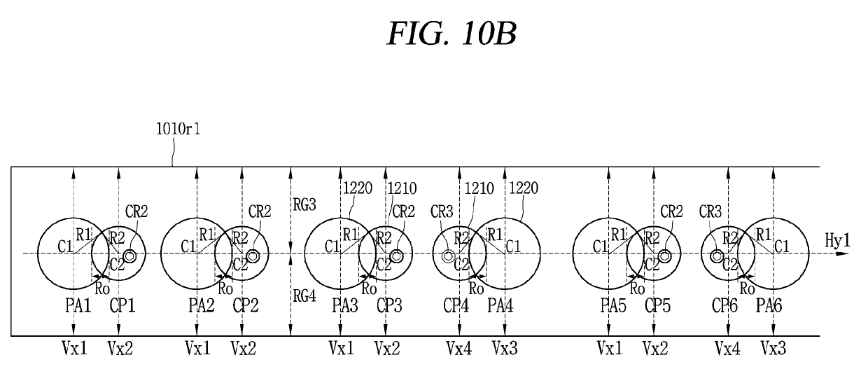

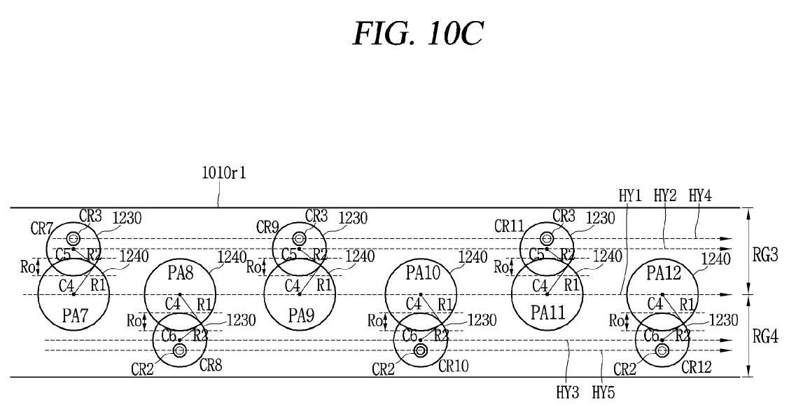

Hereinafter, a description will be given of a patch antenna arrangement structure of the antenna module 1000 implemented as the multi-layered antenna package according to the disclosure, with respect to the accompanying drawings. In this regard, FIG. 10A is a view of tenth and twelfth layers on which patch antennas of the antenna module of FIG. 8B are stacked. FIG. 10B is a view of an overlap arrangement structure of horizontal polarization antennas arranged in an array antenna arrangement region of the antenna module of FIG. 10A. FIG. 10C is a view of an overlap arrangement structure of vertical polarization antennas arranged in the array antenna arrangement region of the antenna module of FIG. 10A.

Referring to FIG. 10A, the first patch antennas PA1 to PA6 may be arranged equally at a first gap G1 on the Y-axis. The third patch antennas PA7 to PA12 may be arranged equally at the first gap G1 on the Y-axis. The second patch antennas CP1 and CP2 in first and second columns may be arranged at the first gap G1 on the Y axis.

A distance between the second patch antennas CP3 and CP4 in third and fourth columns and a distance between the second patch antennas CP5 and CP6 in fifth and sixth columns may be a third gap G3, which is narrower than the first gap G1, on the Y-axis. A distance between the second patch antennas CP4 and CP5 in fourth and fifth columns may be a fourth gap G4, which is wider than the first gap G1, on the Y-axis. A distance between the second patch antennas CP7 and CP9 in seventh and ninth columns may be a second gap G2, which is wider than the third gap G3, on the Y axis. A distance between the second patch antennas CP8 and CP10 in eighth and tenth columns may be the second gap G2 on the Y-axis. The second gap G2 may be two times wider than the first gap G1.

Referring to FIG. 10B, the first patch antennas 1220 and the second patch antennas 1210 may be arranged on a first horizontal axis Hy1 corresponding to the center of the array antenna arrangement region 1010r1.

Among the first patch antennas 1220, the centers of patch antennas PA1, PA2, PA3, and PA5 of a first group may be aligned on a first vertical axis Vx1. Among the second patch antennas 1210, the centers of patch antennas CP1, CP2, CP3, and CP5 of a first group may be aligned on a second vertical axis Vx2. The second vertical axis Vx2 may be arranged to be spaced apart from the first vertical axis Vx1 in parallel in a positive Y-axis direction.

Among the first patch antennas 1220, the centers of patch antennas PA4 and PA6 of a second group may be aligned on a third vertical axis Vx3. Among the second patch antennas 1210, the centers of patch antennas CP4 and CP6 of a second group may be aligned on a fourth vertical axis Vx4. The fourth vertical axis Vx4 may be arranged to be spaced apart from the third vertical axis Vx3 in parallel in a negative Y-axis direction.

The first patch antenna 1220 may be configured as a circular patch antenna having a first diameter R1. The second patch antenna 1210 may be configured as a circular patch antenna having a second diameter R2 smaller than the first diameter R1. The first patch antenna 1220 and the second patch antenna 1210 may be arranged to have an arcuate overlap region Ro on a horizontal axis. The length of the overlap region Ro between the first and second patch antennas 1220 and 1210 may be smaller than the second diameter R2 of the second patch antenna 1210.

Upon connection-to-connection regions CR2 and CR3 through feed vias at offset points, for example, right and left points of the second patch antennas 1210, a polarization of electromagnetic wave radiated from the second patch antenna 1210 is formed only in right and left directions. The connection regions CR2 and CR3 are formed at offset points by predetermined distances from the center points of the second patch antennas 1210.

A current distribution in regions adjacent to the connection regions CR2 and CR3 appears higher than that in surrounding regions. A mode formed on the second patch antenna on which the current distribution is made in the left and right directions is a TE11 mode.

The connection regions CR2 and CR3 may be formed on the second patch antennas 1210 in directions away from the centers of the second patch antennas 1210 in the Y-axis direction. Therefore, the current generated on the second patch antennas 1210 in the left and right directions produces a dominant current distribution. Accordingly, the antenna elements including the first and second patch antennas 1220 and 1210 operate in the TE11 mode. This increases left and right co-polarization radiation performance, other than top and bottom cross-polarization, thereby improving antenna gain performance.

Top and bottom current components are attenuated by the TE11 mode, so as to substantially disappear. Therefore, the co-polarization radiation performance corresponding to horizontal polarization increases and the antenna gain is improved. Also, the cross-polarization components can be reduced, and thus data throughput performance improvement can be expected by virtue of MIMO performance improvement.

Referring to FIG. 10C, the third patch antennas 1240 may be arranged on the first horizontal axis Hy1 corresponding to the center of the array antenna arrangement region 1010r1. Among the fourth patch antennas 1230, the centers of patch antennas of a first group may be aligned on the second horizontal axis Hy2 and arranged in the third region RG3. The second horizontal axis Hy2 may be arranged in the third region RG3 at a certain distance from the first horizontal axis Hy1. Among the fourth patch antennas 1230, the centers of patch antennas of a second group may be aligned on a third horizontal axis Hy3 and arranged in a fourth region RG4. The third horizontal axis Hy3 may be arranged in the fourth region RG4 at a certain distance from the first horizontal axis Hy1.

The third patch antenna 1240 may be configured as a circular patch antenna having a first diameter R1. The fourth patch antenna 1230 may be configured as a circular patch antenna having a second diameter R2 smaller than the first diameter R1. The third patch antenna 1240 and the fourth patch antenna 1230 may be arranged to have an arcuate overlap region Ro in a vertical axis direction. The overlap region Ro between the third patch antenna 1240 and the fourth patch antenna 1230 belonging to the first group may be arranged in the third region RG3. The overlap region Ro between the third patch antenna 1240 and the fourth patch antenna 1230 belonging to the second group may be arranged in the fourth region RG4. The length of the overlap region Ro between the third and fourth patch antennas 1240 and 1230 may be smaller than the second diameter R2 of the fourth patch antenna 1230.

Upon connection to the connection regions CR2 and CR3 through feed vias at offset points, for example, upper and lower points of the fourth patch antennas 1230, a polarization of electromagnetic waves radiated from the fourth patch antennas 1230 is formed only in upper and lower directions. The connection regions CR2 and CR3 are formed at offset points by predetermined distances from the center points of the fourth patch antennas 1230.

A current distribution in regions adjacent to the connection regions CR2 and CR3 appears higher than that in surrounding regions. A mode formed on the fourth patch antenna 1230 on which the current distribution is made in the upper and lower directions is the TE11 mode.

The connection regions CR2 and CR3 may be formed on the fourth patch antennas 1230 in directions away from the centers of the fourth patch antennas 1230 in the Y-axis direction. Therefore, the current generated on the fourth patch antenna 1230 in the upper and lower directions produces a dominant current distribution. Accordingly, the antenna elements including the third and fourth patch antennas 1240 and 1230 operate in the TE11 mode. This increases top and bottom co-polarization radiation performance, other than left and right cross-polarization, thereby improving antenna gain performance.

Left and right current components are attenuated by the TE11 mode, so as to substantially disappear. Therefore, the co-polarization radiation performance corresponding to vertical polarization increases and the antenna gain is improved. Also, the cross-polarization components can be reduced, and thus data throughput performance improvement can be expected by virtue of MIMO performance improvement.

Hereinafter, an antenna module implemented as a multi-layered antenna package according to the disclosure will be described with reference to FIGS. 2 to 10C. The antenna module 1000 implemented as the multi-layered antenna package may include a PCB 1010, a phased array antenna portion 1200, an RFIC chip 1400, and a plurality of signal connection lines SL1 to SL4.

The PCB 1010 may include a plurality of layers. The PCB 1010 may include a plurality of conductive plates and dielectric layers. The plurality of conductive plates may be stacked with the dielectric layers interposed therebetween to be electrically separated from one another.

The phased array antenna portion 1200 may be arranged on a first outermost surface of the PCB 1010. A first surface S1 which is the first outermost surface of the PCB 1010 may include a metal layer connected to the ground. An inner region of the metal layer of the first surface S1 may be formed as a non-metal region where the phased array antenna portion 1200 is arranged. The non-metal region where the phased array antenna portion 1200 is arranged may correspond to the array antenna arrangement region 1010r1.

A first vertical region VR1 may be formed from the outermost surface of the PCB 1010 to an upper ground layer in an antenna direction, which is an inner layer where the signal connection lines of the third part SL3 are arranged in the PCB 1010. The first vertical region VR1 corresponding to A non-metal region may include a plurality of antenna elements PA1 to PA12 and CP1 to CP12 of the phased array antenna portion 1200 and a dielectric material. The outer peripheral surface of the first vertical region VR1 may form ground walls.

The phased array antenna portion 1200 may include a first region RG1 and a second region RG2 based on a first axial direction. The phased array antenna portion 1200 may include a third region RG3 and a fourth region RG4 based on a second axial direction. The first axial direction and the second axial direction may be orthogonal to each other. The first axial direction and the second axial direction may be the X-axis direction and the Y-axis direction, respectively.

The phased array antenna portion 1200 may include a plurality of antenna elements PA1 to PA12 and CP1 to CP12. Each of the plurality of antenna elements PA1 to PA12 and CP1 to CP12 may be configured to have a structure with two patch antennas. The plurality of antenna elements PA1 to PA12 and CP1 to CP12 of the phased array antenna portion 1200 may include a first array antenna 1200a and a second array antenna 1200b.

The first array antenna 1200a arranged in the first region RG1 may include first patch antennas PA1 to PA6 and second patch antennas CP1 to CP6. The first patch antennas PA1 to PA6 may be arranged on the first surface S1 which is the first outermost surface of the PCB 1010. The first patch antennas PA1 to PA6 may be arranged at a first gap G1 in the second axial direction. The second patch antennas CP1 to CP6 may be arranged on any one of the plurality of layers inside the PCB 1010.

Portions of the first patch antennas CP1 to CP6 and portions of the second patch antennas CP1 to CP12 may be stacked to overlap each other. Portions of the first patch antennas PA1 to PA6 and portions of the second patch antennas CP1 to CP6 may be stacked to overlap each other in the Y-axis direction which is the second axial direction. Centers of the first patch antennas PA1 to PA6 and centers of the second patch antennas CP1 to CP6 may be aligned along the same axis, for example, the second axis.

The array antenna 1200b arranged in the second region RG2 may include third patch antennas PA7 to PA12 and fourth patch antennas CP7 to CP12. The third patch antennas PA7 to PA12 may be arranged on the first surface S1 which is the first outermost surface of the PCB 1010. The third patch antennas PA7 to PA12 may be arranged at the first gap G1 in the second axial direction. The fourth patch antennas CP7 to CP12 may be arranged on any one of the plurality of layers inside the PCB 1010.

Portions of the third patch antennas PA7 to PA12 and portions of the fourth patch antennas CP7 to CP12 may be stacked to overlap each other. Portions of the third patch antennas PA7 to PA12 and portions of the fourth patch antennas CP7 to CP12 may be stacked to overlap each other in the X-axis direction which is the first axial direction.

A first group of the fourth patch antennas CP7 to CP12 may be arranged in the third region. The first group of the fourth patch antennas CP7 to CP12 may be seventh, ninth, and eleventh antenna elements PA7, PA9, and PA11. The first group of the fourth patch antennas CP7 to CP12 may be arranged at a second gap G2 along the second axial direction. A second group of the fourth patch antennas CP7 to CP12 may be arranged in the fourth region RG4. The second group of the fourth patch antennas CP7 to CP12 may be eighth, tenth, and twelfth antenna elements PA8, PA10, and PA12. The second group of the fourth patch antennas CP7 to CP12 may be arranged at the second gap G2 along the second axial direction.

The first patch antennas PA1 to PA6 and the second patch antennas CP1 to CP6 may operate as horizontal polarization antennas, which form a first beamforming signal by receiving first signals and second signals in the second axial direction. The third patch antennas PA7 to PA12 and the fourth patch antennas CP7 to CP12 may operate as vertical polarization antennas, which form a second beamforming signal by receiving third signals and fourth signals in the first axial direction. The second patch antennas CP1 to CP6 and the fourth patch antennas CP7 to CP12 may receive the first to fourth signals of a certain phase value such that the first beamforming signal and the second beamforming signal are oriented in the same direction. Accordingly, the phased array antenna portion 1200 can operate as a dual polarization antenna that simultaneously receives or simultaneously transmits a horizontal polarization signal and a vertical polarization signal.

Among the patch antennas, the first and third patch antenna PA1 to PA12 may be located on the first surface S1 of the PCB 1010, and the first surface S1 may be the first outermost surface of the PCB 1010. Among the patch antennas, the second and fourth patch antennas CP1 to CP12 may be located inside the PCB 1010. The second and fourth patch antennas CP1 to CP12 may be arranged on the same one layer among the plurality of layers inside the PCB 1010.

The RFIC chip 1400 may be arranged to be bonded to a second surface S2 of the PCB 1010 opposite to the first surface S1. The RFIC chip 1400 may be bonded to the second surface S2 which is a second outermost surface of the PCB 1010.

The plurality of signal connection lines SL1 to SL4 may be configured to electrically connect the RFIC chip 1400 and the plurality of antenna elements of the second and fourth patch antennas CP1 to CP12. Each of the plurality of signal connection lines SL1 to SL4 may be fed by being connected to the second and fourth patch antennas CP1 to CP12 inside the PCB 1010. Each of the plurality of signal connection lines SL1 to SL4 may be configured not to be directly connected to the first and third patch antennas PA1 to PA12 on the first surface S1 of the PCB 1010.

The plurality of signal connection lines SL1 to SL4 may be configured to connect the RFIC chip 1400 to the phased array antenna portion 1200. A length of each of the plurality of signal connection lines SL1 to SL4 may be a connection length between the RFIC chip 1400 and the phased array antenna portion 1200. Each of the plurality of signal connection lines SL1 to SL4 may be connected to the second and fourth patch antennas 1210 inside the PCB 1010.

Each of the plurality of signal connection lines SL1 to SL4 may be connected to the second patch antenna CP1 to CP6 inside the PCB 1010. The lengths of the plurality of signal connection lines SL1 to SL4 may correspond to first connection lengths Lc1 between the RFIC chip 1400 and the second patch antennas CP1 to CP6. The first connection lengths Lc1 of the plurality of signal connection lines SL1 to SL4 may be the same with respect to the respective second patch antennas CP1 to CP6. Accordingly, signals applied from the RFIC chip 1400 to all the second patch antennas CP1 to CP6 can be in phase, and beams can be formed toward a center point.

Each of the plurality of signal connection lines SL1 to SL4 may be connected to the fourth patch antennas CP7 to CP12 inside the PCB 1010. The lengths of the plurality of signal connection lines SL1 to SL4 may correspond to second connection lengths Lc2 between the RFIC chip 1400 and the fourth patch antennas CP7 to CP12. The second connection lengths Lc2 of the plurality of signal connection lines SL1 to SL4 may be the same with respect to the respective fourth patch antennas CP7 to CP12. Accordingly, signals applied from the RFIC chip 1400 to all the fourth patch antennas CP7 to CP12 can be in phase, and beams can be formed toward a center point. As another example, the second connection length Lc2 may be formed differently from the first connection length Lc1.

The lengths of the plurality of signal connection lines SL1 to SL4 correspond to connection lengths between the RFIC chip 1400 and the second and fourth patch antennas 1210 and 1230. The plurality of signal connection lines SL1 to SL4 may include feed lines Fc1 to Fc12 connected to the second and fourth patch antennas PA1 to PA12 of the phased array antenna portion 1200.

Among the plurality of signal connection lines SL1 to SL4, signal connection lines of the first part SL1 arranged horizontally on the first layer La1 have the same length. Signal connection lines of the second part SL2 connected to the first part SL1 and arranged vertically on the inner layers of the PCB 1010 have the same length. Signal connection lines of the third part SL3 connected to the second part SL2 and horizontally arranged on one layer inside the PCB 1010 have the same length.

Signal connection lines of the fourth part SL4 arranged vertically to be connected to the third part SL3 and the second patch antennas 1210 have the same length. First signal connection lines of the fourth part SL4 may have the same first connection length with respect to each of the second patch antennas CP1 to CP6. Second signal connection lines of the fourth part SL4 arranged vertically to be connected to the third part SL3 and the fourth patch antennas CP7 to CP12 have the same length. The second signal connection lines of the fourth part SL4 may have the same second connection length with respect to each of the fourth patch antennas CP7 to CP12.

Among the plurality of signal connection lines, the signal connection lines of the first part SL1 arranged horizontally on the first layer La1 may include a first group and a second group. The first group of signal connection lines of the first part SL1 may be connected to first, third, sixth, eighth, tenth, and twelfth antenna elements. The second group of signal connection lines of the first part SL1 may be connected to second, fourth, fifth, seventh, ninth, and eleventh antenna elements.

The plurality of signal connection lines of the first part SL1 may be electrically connected to the second patch antennas CP1 to CP6 and the fourth patch antennas CP7 to CP12. Among the plurality of signal connection lines of the first part SL1, the first group of signal connection lines may be arranged in a fourth region RG4 based on the first horizontal axis Hy1. Among the plurality of signal connection lines of the first part SL1, the second group of signal connection lines may be arranged in a third region RG3 based on the first horizontal axis Hy1. Accordingly, six connection pins may be assigned to each of upper and lower regions of the RFIC chip 1400 of the first layer La1, to transmit signals to the second patch antennas CP1 to CP6 and the fourth patch antennas CP7 to CP12.

Signal connection lines of the second part SL2, which are connected to the plurality of signal connection lines of the first part SL1 and arranged vertically as the inner layers of the PCB 1010, may include a first group and a second group. The first group of signal connection lines of the second part SL2 may be connected to first, third, sixth, eighth, tenth, and twelfth antenna elements. The second group of signal connection lines of the second part SL2 may be connected to second, fourth, fifth, seventh, ninth, and eleventh antenna elements.

The plurality of signal connection lines of the second part SL2 may be electrically connected to the second patch antennas CP1 to CP6 and the fourth patch antennas CP7 to CP12. Among the plurality of signal connection lines of the second part SL2, the first group of signal connection lines may be arranged in the fourth region RG4 based on the first horizontal axis Hy1. Among the plurality of signal connection lines of the second part SL2, the second group of signal connection lines may be arranged in the third region RG3 based on the first horizontal axis Hy1. Accordingly, six via connection structures connecting the first layer La1 and the seventh layer La7 can be formed in each of the third region RG3 and the fourth region RG4 of the PCB 1010. The via connection structures of the second part SL2 connecting the first layer La1 and the seventh layer La7 can be formed to transmit signals to the second patch antennas CP1 to CP6 and the fourth patch antennas CP7 to CP12.

First signal connection lines of the fourth part SL4, which are connected to the plurality of signal connection lines of the third part SL3 and arranged vertically to be connected to the second patch antennas CP1 to CP6, may be formed on the same axis as the first horizontal axis Hy1. Among the plurality of signal connection lines, first and second groups of second signal connection lines of the fourth part SL4, which is connected to the third part SL3 and vertically arranged to be connected to the fourth patch antennas CP7 to CP12, may be arranged in the third region RG3 and the fourth region RG4, respectively. The first group of second signal connection lines arranged in the third region RG3 may be connected to the first group of patch antennas PA7, PA9, and PA11 of the fourth patch antennas CP7 to CP12. The second group of second signal connection lines arranged in the fourth region RG4 may be connected to the second group of patch antennas PA8, PA10, and PA12 of the fourth patch antennas CP7 to CP12.

Among the plurality of signal connection lines SL1 to SL4, the signal connection lines of the third part SL3 may be formed as a coplanar waveguide structure in which the grounds are arranged on opposite sides. The inner layers, on which the signal connection lines of the third part SL3 among the plurality of signal connection lines SL1 to SL4 are arranged, may include an upper ground layer in the antenna direction and a lower ground layer in the RFIC direction. The signal connection lines of the third part SL3 among the plurality of signal connection lines SL1 to SL4 may be arranged on the seventh layer La7. The upper ground layer in the antenna direction may be a ground layer formed on the eighth layer La8. The lower ground layer in the RFIC direction may be a third ground layer GND3 formed on the sixth layer La6.

The antenna module 1000 implemented as the multi-layered antenna package may be configured to include a plurality of array antennas arranged in different regions of the PCB 1010. The antenna module 1000 may also include the phased array antenna portion 1200, the first and second array antennas 1100a and 1100b, and the fourth array antenna 1300.

The first and second array antennas 1100a and 1100b may include first resonating elements DA21 to DA26 arranged on one side region and another side region of the PCB 1010. The first and second array antennas 1100a and 1100b may be configured to radiate signals toward one side and another side of an electronic device where the PCB 1010 is arranged.

The phased array antenna portion 1200 may include a plurality of antenna elements PA1 to PA12 and CP1 to CP12 arranged on the central region CR of the PCB 1010. The phased array antenna portion 1200 may be configured to radiate signals toward the bottom of the electronic device where the PCB 1010 is arranged.

The fourth array antenna 1300 may include second resonating elements DA1 to DA14 arranged in the lower region of the PCB 1010. The fourth array antenna 1300 may be configured to radiate signals in the X-axis direction of the PCB 1010.

The first and second array antennas 1100a and 1100b may operate as horizontal polarization antennas that transmit signals in the Y-axis direction and have polarization in the X-axis direction. The first and second array antennas 1100a and 1100b may operate as horizontal polarization antennas that receive and transmit signals to a communication apparatus in the Y-axis direction and form an electric field in the X-axis direction. The phased array antenna portion 1200 may operate as a vertical polarization antenna that transmits signals in the Z-axis direction and has polarization in the X-axis direction. The phased array antenna portion 1200 may operate as a vertical polarization antenna that receives and transmits signals to the communication apparatus in the Z-axis direction and form an electric field in the Y-axis direction.

The fourth array antenna 1300 may operate as a horizontal polarization antenna that transmits signals in the X-axis direction and has polarization in the Y-axis direction. The fourth array antenna 1300 may operate as a horizontal polarization antenna that receives and transmits signals to the communication apparatus in the X-axis direction and has polarization in the Y-axis direction.

Surfaces on which the first and second array antennas 1100a and 1100b and the fourth array antenna 1300 are arranged are formed at positions perpendicular to each other. The signal transmission and reception direction of the first and second array antennas 1100a and 1100b and the signal transmission and reception direction of the fourth array antenna 1300 are perpendicular to each other.

Surfaces on which the first and second array antennas 1100a and 1100b and the phased array antenna portion 1200 are arranged at positions perpendicular to each other. The signal transmission and reception direction of the first and second array antennas 1100a and 1100b and the signal transmission and reception direction of the phased array antenna portion 1200 are perpendicular to each other.

Surfaces on which the phased array antenna portion 1200 and the fourth array antenna 1300 are arranged are formed at positions perpendicular to each other. The signal transmission and reception direction of the phased array antenna portion 1200 and the signal transmission and reception direction of the fourth array antenna 1300 are perpendicular to each other.

In some embodiments, the antenna module 1000 implemented as the multi-layered antenna package may be configured to include a plurality of dielectric layers and coplanar waveguide layers. The antenna module 1000 may include a first dielectric layer DL1, a second dielectric layer DL2, and a third dielectric layer DL3. The antenna module 1000 may include a first coplanar waveguide layer WG1, a second coplanar waveguide layer WG2, and a third coplanar waveguide layer WG3.

The first dielectric layer DL1 may be arranged directly on a surface of an interface layer IL of the RFIC chip 1400. The first coplanar waveguide layer WG1 may be arranged on the first dielectric layer DL1 in a height direction. The first coplanar waveguide layer WG1 may be configured to receive an RF signal transmitted by the interface layer IL of the RFIC chip 1400 and transmit the received RF signal to the first and second array antennas 1100a and 1100b. The first coplanar waveguide layer WG1 may be configured to transmit the RF signal received from the first and second array antennas 1100a and 1100b to the interface layer IL of the RFIC chip 1400.

The second dielectric layer DL2 may be arranged on the first coplanar waveguide layer WG1. The second coplanar waveguide layer WG2 may be arranged on the second dielectric layer DL2. The second coplanar waveguide layer WG2 may be configured to receive an RF signal transmitted by the interface layer IL of the RFIC chip 1400 and transmit the received RF signal to the fourth array antenna 1300. The second coplanar waveguide layer WG2 may be configured to transmit the RF signal received from the fourth array antenna 1300 to the interface layer IL of the RFIC chip 1400.

The third dielectric layer DL3 may be arranged on the second coplanar waveguide layer WG2. The third coplanar waveguide layer WG3 may be arranged on the third dielectric layer DL3. The third coplanar waveguide layer WG3 may be configured to receive an RF signal transmitted by the interface layer IL of the RFIC chip 1400 and transmit the received RF signal to the phased array antenna portion 1200. The third coplanar waveguide layer WG3 may be configured to transmit the RF signal received from the phased array antenna portion 1200 to the interface layer IL of the RFIC chip 1400. The third coplanar waveguide layer WG3 may include thereon a plurality of second signal connection lines Fc1 to Fc12 and a ground portion GP3.

The RFIC chip 1400 may be arranged on the interface layer IL which is the first layer La1 of the PCB 1010. The first to third coplanar waveguide layers WG1, WG2, and WG3 may be arranged on the third, fifth, and seventh layers La3, La5, and La7 of the PCB 1010. The first, second, and third ground layers GND1, GND2, and GND3 may be arranged on the second, fourth, and sixth layers La2, La4, and La6 of the PCB 1010.

The plurality of signal connection lines SL1 to SL4 may include a first part SL1, a second part SL2, a third part SL3, and a fourth part SL4. The first part SL1 is horizontally arranged on the first layer La1. The second part SL2 is connected to the first part SL1 and is vertically arranged as an inner layer of the PCB 1010. The third part SL3 is connected to the second part SL2 and is horizontally arranged on any one layer inside the PCB 1010. The fourth part SL4 is vertically arranged to be connected to the third part SL3 and the second patch antennas 1210.

The first part SL1 of the plurality of signal connection lines may be arranged on the first layer La1 of the PCB 1010. The second part SL2 of the signal connection lines may correspond to first vertical vias connecting the first layer La1 and the seventh layer La7 of the PCB 1010. The third part SL3 of the plurality of signal connection lines may correspond to the feed lines Fc1 to Fc12 arranged on the seventh layer La7 of the PCB 1010. The fourth part SL4 of the plurality of signal connection lines may correspond to second vertical vias connecting ends of the feed lines Fc1 to Fc12 and the second patch antennas 1210.

First and second patch antennas 1220 and 1210 may be arranged inside the PCB 1010. The first and second patch antennas 1220 and 1210 may be arranged inside the array antenna arrangement region 1010r1 of the PCB 1010. A first group of second patch antennas 1210 arranged inside the PCB 1010 may be electrically connected to the fourth parts SL4 of the signal feed lines in the first region RG1 based on a center line of an inner layer where the second patch antennas 1210 are arranged. A second group of second patch antennas 1210 arranged inside the PCB 1010 may be electrically connected to the fourth parts SL4 of the signal feed lines in the second region RG2 based on the center line of the inner layer where the second patch antennas 1210 are arranged.

Signals applied from the RFIC chip 1400 to the second patch antennas CP1 to CP6 through the signal connection lines SL1 to SL4 may include first signals and second signals. Among the signals applied to the second patch antennas CP1 to CP6, the first signals may be applied to the first group of patch antennas CP1, CP2, CP3, and CP5 among the second patch antennas CP1 to CP6. Among the signals applied to the second patch antennas CP1 to CP6, the second signals may be applied to the second group of patch antennas CP4 and CP6 among the second patch antennas CP1 to CP6. The first signals applied to the first group of patch antennas CP1, CP2, CP3, and CP5 may be controlled to have the same phase. The second signals applied to the second group of patch antennas CP4 and CP6 may be controlled to have the same phase. The first signals applied to the first group of patch antennas CP1, CP2, CP3 and CP5 and the second signals applied to the second group of patch antennas CP4 and CP6 may be controlled to have a phase difference of 180 degrees.

Signals applied from the RFIC chip 1400 to the fourth patch antennas CP7 to CP12 through the signal connection lines SL1 to SL4 may include third signals and fourth signals. Among the signals applied to the fourth patch antennas CP7 to CP12, the third signals may be applied to the first group of patch antennas CP7, CP9, and CP11 among the fourth patch antennas CP7 to CP12. Among the signals applied to the fourth patch antennas CP7 to CP12, the fourth signals may be applied to the second group of patch antennas CP8, CP10, and CP12 among the fourth patch antennas CP7 to CP12. The third signals applied to the first group of patch antennas CP7, CP9, and CP11 may be controlled to have the same phase. The fourth signals applied to the second group of patch antennas CP8, CP10, and CP12 may be controlled to have the same phase. The third signals applied to the first group of patch antennas CP7, CP9 and CP11 and the fourth signals applied to the second group of patch antennas CP8, CP10, and CP12 may be controlled to have a phase difference of 180degrees.

A first length R1, which is the radius of the first patch antennas PA1 to PA6, may be longer than a second length R1, which is the radius of the second patch antennas CP1 to CP6. The centers C2 and C3 of the second patch antennas CP1 to CP6 and the center C1 of the first patch antennas PA1 to PA6 may be arranged equally in the direction of the first horizontal axis Hy1. The second patch antennas CP1 to CP6 and the first patch antennas PA1 to PA6 may partially overlap each other in certain regions.

Among the second patch antennas CP1 to CP6, the first group of patch antennas CP3 and CP5 may be arranged spaced apart by a third gap G3 from the second group of patch antennas CP4 and CP6 adjacent to the first group of path antennas CP3 and CP5. The third gap G3 may be narrower than the first gap G1 of the first patch antennas PA1 to PA12. Among the second patch antennas CP1 to CP6, the patch antenna CP4 of the second group may be arranged spaced apart by a fourth gap GP4 from the adjacent patch antenna CP5 of the first group. The fourth gap G4 may be wider than the first gap G1 of the first patch antennas PA1 to PA12. The sum of the third gap G3 and the fourth gap G4 may be the same as the second gap G2 of the first group of patch antennas CP7, CP9, and CP11 of the fourth patch antennas CP7 to CP12.

Among the fourth patch antennas CP7 to CP12, the centers C5 of the first group of the patch antennas CP7, CP9, and CP11 may be aligned in the direction of the second vertical axis Hy2. The centers C5 of the first group of patch antennas CP7, CP9, and CP11 may be aligned along the second horizontal axis Hy2, which is be spaced apart in parallel by a certain gap from the first horizontal axis Hy1 toward the third region RG3. The third patch antennas PA7 to PA12 may be arranged on the first horizontal axis Hy1. Among the fourth patch antennas CP7 to CP12, the centers C6 of the second group of patch antennas CP8, CP10, and CP12 may be aligned along the third horizontal axis Hy3. The centers C6 of the second group of patch antennas CP8, CP10, and CP12 may be aligned along the third horizontal axis Hy3, which is be spaced apart in parallel by a certain gap from the first horizontal axis Hy1 toward the fourth region RG4.

First connection regions CR2 and CR3 of the second patch antennas CP1 to CP6 connected to the fourth parts SL4 of the signal connection lines may be formed on the same axis in the direction of the first horizontal axis Hy1. The first connection regions CR2 and CR3 may be arranged in regions spaced apart from the centers C2 and C3 of the second patch antennas CP1 to CP6. The first connection regions CR2 and CR3 may be arranged in regions opposing the overlap regions Ro based on the centers C2 and C3 of the second patch antennas CP1 to CP6.

Second connection regions CR5 of the first group of patch antennas CP7, CP9, and CP10 among the fourth patch antennas CP7 to CP12 connected to the fourth part SL4 of the signal connection lines may be aligned on a fourth horizontal axis Hy4, which is spaced apart from the second horizontal axis Hy2. Third connection regions CR6 of the second group of patch antennas CP8, CP10, and CP12 among the fourth patch antennas CP7 to CP12 connected to the fourth part SL4 of the signal connection lines may be aligned on a fifth horizontal axis Hy5, which is spaced apart from the third horizontal axis Hy3. The second and third connection regions CR5 and CR6 may be arranged in regions spaced apart from the centers C5 and C6 of the second patch antennas CP7 to CP12. The second and third connection regions CR5 and CR6 may be arranged in regions opposing the overlap regions Ro based on the centers C5 and C5 of the second patch antennas CP7 to CP12.

The feed lines Fc1 to Fc12 may include upper feed lines Fc2, Fc4, Fc5, Fc7, Fc9, and Fc11 arranged in the third region RG3, and lower feed lines Fc1, Fc3, Fc6, Fc8, Fc10, and Fc12 arranged in the fourth region RG4. The lower feed lines Fc1, Fc3, Fc6, Fc8, Fc10, and Fc12 may be connected to the second patch antennas CP1, CP3, CP6, CP8, CP10, and CP12 in first, third, sixth, eighth, tenth, and twelfth columns. The upper feed lines Fc2, Fc4, Fc5, Fc7, Fc9, and Fc11 may be connected to the second patch antennas CP2, CP4, CP5, CP7, CP9, and CP11 in second, fourth, fifth, seventh, ninth, and eleventh columns.

Ends of the upper feed lines Fc2, Fc4, Fc5, Fc7, Fc9, and Fc11 may be arranged in the upper region of the PCB 1010 based on the Y-axis. Ends of the lower feed lines Fc1, Fc3, Fc6, Fc8, Fc10, and Fc12 may be arranged in the lower region of the PCB 1010 based on the Y-axis.

In some embodiments, the RFIC chip 1400 may be connected to a plurality of array antennas through a plurality of pins arranged on a first side surface Sd1 as an upper region, a second side surface Sd2 as one side region, a third side surface Sd3 as another side region, and a fourth side surface Sd4 as a lower region.

Pins on the first side surface Sd1, which is the upper region of the RFIC chip 1400, may be connected to the upper feed lines Fc2, Fc4, Fc5, Fc7, Fc9, and Fc11 through the first vertical vias SL2. Pins on the fourth side surface Sd4, which is the lower region of the RFIC chip 1400, may be connected to the lower feed lines Fc1, Fc3, Fc6, Fc8, Fc10, and Fc12 through the first vertical vias SL2.

In some embodiments, second vertical vias SL4 may be arranged on the eighth, ninth, and tenth layers La8, La9, and La10 of the PCB 1010. The second and fourth patch antennas CP1 to CP12 may be arranged on the tenth layer La10 of the PCB 1010. Ends of the second vertical vias SL4 may be connected to the second and fourth patch antennas CP1 to CP12 of the tenth layer La10. The first and third patch antennas PA1 to PA12 may be arranged on the twelfth layer La12 of the PCB 1010. The second and fourth patch antennas CP1 to CP12 may be configured not to be connected to the first and third patch antennas PA1 to PA12. The second and fourth patch antennas CP1 to CP12 may be electrically connected to the first and third patch antennas PA1 to PA12 through coupling.

Connection points Vb1 to Vb12 of the first vertical vias SL2 arranged on the seventh layer La7 of the PCB 1010 may be symmetrically aligned with respect to the X-axis of the center line of the PCB 1010. Feeding points Fc1 to Fc12 of the second vertical vias SL4 connected to the second and fourth patch antennas CP1 to CP12 may be symmetrically aligned with respect to the X-axis of the center line of the PCB 1010.

The second patch antennas CP1, CP3, CP6, CP8, CP10, and CP12 in the first, third, sixth, eighth, tenth, and twelfth columns and the first, third, sixth, eighth, tenth, and twelfth feed lines Fc1, Fc3, Fc6, Fc8, Fc10, and Fc12 may be connected by the second vertical vias SL4. The second vertical vias SL4 are electrically connected by the first, third, sixth, eighth, tenth, and twelfth feed lines Fc1, Fc3, Fc6, Fc8, Fc10, and Fc12 arranged in the fourth region RG4. The second patch antennas CP2, CP4, CP5, CP7, CP9, and CP11 in the second, fourth, fifth, seventh, ninth, and eleventh columns and the second, fourth, fifth, seventh, ninth, and eleventh feed lines Fc2, Fc4, Fc5, Fc7, Fc9, and Fc11 may be connected by the second vertical vias SL4. The second vertical vias SL4 are electrically connected by the second, fourth, fifth, seventh, ninth, and eleventh feed lines Fc2, Fc4, Fc5, Fc7, Fc9, and Fc11 arranged in the third region RG3.

The first and second array antennas 1100a and 1100b may be arranged in one side region and another side region on the XY plane of the first coplanar waveguide layer WG1. The fourth array antenna 1300 may be arranged in the lower region based on the Y-axis on the XY plane of the second coplanar waveguide layer WG2. The first, third, sixth, eighth, tenth, and twelfth feed lines Fc1, Fc3, Fc6, Fc8, Fc10, and Fc12 of the phased array antenna portion 1200 may be arranged in the lower region based on the Y-axis on the XY plane of the third coplanar waveguide layer WG3. The second, fourth, fifth, seventh, ninth, and eleventh feed lines Fc2, Fc4, Fc5, Fc7, Fc9, and Fc11 of the phased array antenna portion 1200 may be arranged in the upper region based on the Y-axis on the XY plane of the third coplanar waveguide layer WG3.

The first and second array antennas 1100a and 1100b may be implemented as 1x3 dipole antennas DA21 to DA23 and DA24 to DA26 in one side region and another side region on the XY plane of the first coplanar waveguide layer WG1, respectively. The fourth array antenna 1300 may be implemented as a 1x14 dipole antenna in the lower region based on the Y-axis on the XY plane of the second coplanar waveguide layer WG1. The phased array antenna portion 1200 may be implemented as a 1x12 patch antenna on the center portion of the third coplanar waveguide layer WG3 of the PCB 1010.

The foregoing description has been given of an antenna module implemented with a multi-layered substrate. Hereinafter, technical effects of an antenna module implemented as a multi-layered substrate according to the present disclosure will be described.

The multi-layered circuit type antenna package described above provides a dual polarization antenna structure which can suppress quality of signals transmitted and received through array antennas from being deteriorated due to changes in polarization direction according to changes in radio environment.

The multi-layered circuit type antenna package presents a structure which can wirelessly transmit broadband signals by minimizing the number of stacked layers.

The multi-layered circuit type antenna package has low loss during signal transmission and is economical in process cost.

Further scope of applicability of the disclosure will become apparent from the following detailed description. It should be understood, however, that the detailed description and specific examples, such as the preferred embodiment of the present disclosure, are given by way of illustration only, since various modifications and alternations within the idea and similar scope of the disclosure will be apparent to those skilled in the art. Therefore, all changes and modifications that fall within the metes and bounds of the claims, or equivalents of such metes and bounds are therefore intended to be embraced by the appended claims.

What is claimed is:

1. An antenna module implemented in a multi-layered package, the antenna module comprising:
a printed circuit board (PCB) having a plurality of layers;
a phased array antenna portion arranged on a first outermost surface of the PCB and comprising a plurality of antenna elements, wherein
the phased array antenna portion has a first region and a second region based on a first axial direction,
the phased array antenna portion has a third region and a fourth region based on a second axial direction, and
the first axis and the second axis are orthogonal to each other;
a radio frequency integrated circuit (RFIC) chip bonded to a second outermost surface of the PCB; and
a plurality of signal connection lines configured to electrically connect the RFIC chip and the phased array antenna portion,
wherein the plurality of antenna elements comprise a first array antenna and a second array antenna,
the first array antenna arranged in the first region comprises:
first patch antennas arranged on the first outermost surface of the PCB, the first patch antennas being arranged spaced apart at a first gap along the second axial direction; and
second patch antennas arranged on one of the plurality of layers inside the PCB,
portions of the first patch antennas and portions of the second patch antennas are stacked to overlap each other,
centers of the first patch antennas and centers of the second patch antenna are aligned along a same axis,
the second array antenna arranged in the second region comprises:
third patch antennas arranged on the first outermost surface of the PCB, wherein the third patch antennas are arranged spaced apart at the first gap along the second axial direction; and
fourth patch antennas arranged on one of the plurality of layers inside the PCB,
portions of the third patch antennas and portions of the fourth patch antennas are stacked to overlap each other,
a first group of the fourth patch antennas are arranged in the third region, and positioned at a second gap along the second axial direction, and
a second group of the fourth patch antennas are arranged in the fourth region, and positioned at the second gap along the second axial direction.

2. The antenna module of claim 1, wherein
the first patch antennas and the second patch antennas operate as horizontal polarization antennas which form a first beamforming signal by receiving first signals and second signals of the second axial direction, and
the third patch antennas and the fourth patch antennas operate as vertical polarization antennas which form a second beamforming signal by receiving third signals and fourth signals of the first axial direction.

3. The antenna module of claim 1, wherein
signals applied from the RFIC chip to the second patch antennas through the signal connection lines comprise:
first signals applied to a first group of patch antennas among the second patch antennas; and
second signals applied to a second group of patch antennas among the second patch antennas,
the first signals have a same phase,
the second signals have a same phase,
the first signals and the second signals are controlled to have a phase difference of 180 degrees,
signals applied from the RFIC chip to the fourth patch antennas through the signal connection lines comprise:
third signals applied to the first group of patch antennas among the fourth patch antennas; and
fourth signals applied to the second group of patch antennas among the fourth patch antennas,
the third signals have a same phase,
the fourth signals have a same phase, and
the third signals and the fourth signals are controlled to have a phase difference of 180 degrees.

4. The antenna module of claim 1, wherein
a first length as a radius of the first patch antennas is longer than a second length as a radius of the second patch antennas,
centers of the second patch antennas and centers of the first patch antennas are arranged equally in a first horizontal axis direction,
portions of the second patch antennas and portions of the first patch antennas overlap each other in certain regions,
a second group of patch antennas, adjacent to a first group of patch antennas, among the second patch antennas, are positioned at a third gap, narrower than the first gap, along the second axial direction, and
the first group of patch antennas, adjacent to the second group of patch antennas, among the second patch antennas, are positioned at a fourth gap, wider than the first gap, along the second axial direction.

5. The antenna module of claim 4, wherein
centers of the first group of patch antennas among the fourth patch antennas are aligned in a second horizontal axis direction, spaced in parallel apart by a certain gap toward the third region from the first horizontal axis on which the third patch antennas are arranged, and
centers of the second group of patch antennas among the fourth patch antennas are aligned in a third horizontal axis direction, spaced in parallel apart by a certain gap toward the fourth region from the first horizontal axis on which the third patch antennas are arranged.

6. The antenna module of claim 5, wherein
first connection regions of the second patch antennas connected to a fourth part of the signal connection lines are formed on a same axis in the first horizontal axis direction,
the first connection regions are arranged in regions spaced apart from the centers of the second patch antennas,
the first connection regions are arranged in regions opposite to the overlap regions based on the centers of the second patch antennas,
second connection regions of the first group of patch antennas among the fourth patch antennas connected to the fourth part of the signal connection lines are aligned in a fourth horizontal axis direction spaced apart from the second horizontal axis,
third connection regions of the second group of patch antennas among the fourth patch antennas connected to the fourth part of the signal connection lines are aligned in a fifth horizontal axis direction spaced apart from the third horizontal axis, and
the second and third connection regions are arranged in regions opposite to the overlap regions based on the centers of the fourth patch antennas.

7. The antenna module of claim 1, wherein
each of the plurality of signal connection lines is connected to the second patch antennas inside the PCB,
lengths of the plurality of signal connection lines correspond to connection lengths between the RFIC chip and the second patch antennas,
the first connection lengths of the plurality of signal connection lines are same,
each of the plurality of signal connection lines is connected to the fourth patch antennas inside the PCB,
lengths of the plurality of signal connection lines correspond to second connection lengths between the RFIC chip and the fourth patch antennas, and
the second connection lengths of the plurality of signal connection lines are same.

8. The antenna module of claim 7, wherein
signal connection lines of a first part, arranged horizontally on a first layer among the plurality of signal connection lines, have a same length,
signal connection lines of a second part, connected to the first part and arranged vertically as an inner layer of the PCB, have a same length,
signal connection lines of a third part, connected to the second part and arranged horizontally on any one layer inside the PCB, have a same length, and
first signal connection lines of the fourth part, arranged vertically to be connected to the third part and the second patch antennas, have a same length.
second signal connection lines of the fourth part, arranged vertically to be connected to the third part and the second patch antennas, have a same length.

9. The antenna module of claim 8, wherein
the signal connection lines of the first part, arranged horizontally on a first layer among the plurality of signal connection lines, comprise a first group and a second group,
the first group of the first part, electrically connected to the second patch antennas and the fourth patch antennas, among the plurality of signal connection lines, is arranged in the fourth region with respect to a first horizontal axis, and
the second group of the first part, electrically connected to the second patch antennas and the fourth patch antennas, among the plurality of signal connection lines, is arranged in the third region with respect to the first horizontal axis.

10. The antenna module of claim 9, wherein
the signal connection lines of the second part, connected to the first part and vertically arranged as the inner layer of the PCB, among the plurality of signal connection lines, comprise a first group and a second group,
the first group of the second part, electrically connected to the second patch antennas and the fourth patch antennas, among the plurality of signal connection lines, is arranged in the fourth region with respect to a first horizontal axis, and
the second group of the second part, electrically connected to the second patch antennas and the fourth patch antennas, among the plurality of signal connection lines, is arranged in the third region with respect to the first horizontal axis.

11. The antenna module of claim 10, wherein
the first signal connection lines of the fourth part, connected to the third part and vertically arranged to be connected to the second patch antennas, among the plurality of signal connection lines, are arranged on the same axis in the horizontal axis direction, and
first group and the second group of the second signal connection lines of the fourth part, connected to the third part and vertically arranged to be connected to the fourth patch antennas, among the plurality of signal connection lines, are arranged in the third region and the fourth region, respectively.

12. The antenna module of claim 8, wherein
the signal connection lines of the third part among the plurality of signal connection lines have a coplanar waveguide structure in which grounds are arranged on opposite sides.

13. The antenna module of claim 12, wherein
the inner layer, on which the signal connection lines of the third part are arranged, among the plurality of signal connection lines, comprises an upper ground layer in a direction toward an antenna and a lower ground layer in a direction toward the RFIC chip.

14. The antenna module of claim 8, wherein
a first surface, as the first outermost surface of the PCB, comprises a metal layer connected to a ground, and
an inner region of the metal layer is formed as a non-metal region in which the phased array antenna portion is arranged.

15. The antenna module of claim 14, wherein
a first vertical region is formed from the outermost surface of the PCB to the upper ground layer in the direction toward the antenna of an inner layer where the signal connection lines of the third part inside the PCB are arranged,
the first vertical region corresponding to the non-metal region comprises the plurality of antenna elements and a dielectric material, and
an outer peripheral surface of the first vertical region forms ground walls.
